(19) United States
(12) Patent Application Publication
(10) Pub. No.: US 2025/0096732 A1
(43) Pub. Date: Mar. 20, 2025

(54) THREE-WAY DOHERTY AMPLIFIER

(71) Applicant: MACOM Technology Solutions Holdings, Inc., Lowell, MA (US)

(72) Inventor: GERARD BOUISSE, SAINT LYS (FR)

(21) Appl. No.: 18/466,921

(22) Filed: Sep. 14, 2023

(51) Int. Cl. H03F 1/02; H03F 3/21

(52) U.S. Cl. CPC H03F 1/0288; H03F 3/211; H03F 2200/451; H03F 2203/21106

(57) ABSTRACT

A three-way Doherty amplifier according to some embodiments includes a first ratio of a gate width of a main amplifier to a first gate width of a first peak amplifier and a second ratio of the gate width of the main amplifier to a second gate width of a second peak amplifier, respectively, are configured to provide a substantially constant load on the main amplifier.

### FIELD

The disclosure relates to three-way Doherty amplifiers that are capable of substantially cancelling or limiting load modulation.

### BACKGROUND

As current mobile communication systems evolve and new communications systems are developed, there is continuing demand for more powerful and efficient power amplifiers that are capable of operating over broader frequency ranges. Many of these communication systems employ mobile devices and access points, such as base stations, that are battery powered. For such communication devices, more efficient power amplifiers yield longer operating times between battery charges.

Given the ever increasing demand for efficiency, the Doherty amplifier has become a popular power amplifier in mobile communication applications, especially base station applications. While relatively efficient compared to its rivals, the Doherty amplifier has a relatively limited bandwidth of operation. For example, a well-designed Doherty amplifier may provide an instantaneous bandwidth of 5 percent, which corresponds to about 100 MHz for a 2 GHz signal and is generally sufficient to support a single communication band. For example, Universal Mobile Telecommunications Systems (UMTS) devices operate in a band between 2.11 and 2.17 GHZ, and thus require an instantaneous bandwidth of 60 MHz (2.17 GHZ-2.11 GHz). A Doherty amplifier can be configured to support an instantaneous bandwidth of 60 MHz for the UMTS band. Accordingly, for communication devices that only need to support a single communication band, the limited operating bandwidth of the Doherty power amplifier may not pose a problem.

However, modern communication devices are often required to support various communication standards that employ different modulation techniques over a wide range of operating frequencies. These standards include but are not limited to the Global System for Mobile Communications (GSM), Personal Communication Service (PCS), Universal Mobile Telecommunications Systems (UMTS), Worldwide Interoperability for Microwave Access (WiMAX), Long Term Evolution (LTE), fifth generation (5G), sixth generation (6G), and the like.

The bands of operation for these standards range from around 800 MHz to at least 20 GHz. The GSM standards employ bands ranging from around 800 MHz to 2 GHz. For example, GSM-850 uses an 824-894 MHz band, GSM-900 uses an 890-960 MHz band, GSM-1800 uses a 1310-1880 MHz band, and GSM-1900 uses an 1850-1990 MHz band. UMTS uses a 2.11-2.17 GHz band. LTE uses a 2.6-2.7 GHz band; WiMAX uses bands centered about 2.3, 2.5, 3.3 and 3.5 GHz; 5G uses a 1-6 GHz range; and 6G may use frequencies in at least the range 7-20 GHz. Thus, for devices that need to support multiple communication bands, a single Doherty amplifier is not sufficient.

For communication devices that support multiple standards over disparate communication bands, designers often employ multiple power amplifier chains for each of the different communication bands, which increases the size, cost, and complexity of the communication devices. As such, there is a need to increase the effective operating range of a Doherty power amplifier to support multiple communication bands, which are spread over a significant frequency range, while maintaining linearity and efficiency.

Narrow bandgap semiconductor materials, such as silicon (Si) and gallium arsenide (GaAs), are widely used in semiconductor devices for low power and, in the case of Si, low frequency applications. However, these semiconductor materials may not be well-suited for high power and/or high frequency applications, for example, due to their relatively small bandgaps (1.12 eV for Si and 1.42 for GaAs at room temperature) and relatively small breakdown voltages.

Interest in high power, high temperature and/or high frequency applications and devices has focused on wide bandgap semiconductor materials such as silicon carbide (3.2 eV for 4H-SiC at room temperature) and the Group III nitrides (e.g., 3.36 eV for GaN at room temperature). These materials may have higher electric field breakdown strengths and higher electron saturation velocities than GaAs and Si.

A device of particular interest for high power and/or high frequency applications is the High Electron Mobility Transistor (HEMT), which is also known as a modulation doped field effect transistor (MODFET). In a HEMT device, a two-dimensional electron gas (2DEG) may be formed at the heterojunction of two semiconductor materials with different bandgap energies, where the smaller bandgap material has a higher electron affinity than the wider bandgap material. The 2DEG is an accumulation layer in the undoped smaller bandgap material and can contain a relatively high sheet electron concentration, for example, in excess of 1013 carriers/cm². Additionally, electrons that originate in the wider bandgap semiconductor may transfer to the 2DEG, allowing a relatively high electron mobility due to reduced ionized impurity scattering. This combination of relatively high carrier concentration and carrier mobility can give the HEMT a relatively large transconductance and may provide a performance advantage over metal-semiconductor field effect transistors (MESFETS) for high-frequency applications.

HEMTs fabricated in the gallium nitride/aluminum gallium nitride (GaN/AlGaN) material system can generate large amounts of RF power due to a combination of material characteristics, such as relatively high breakdown fields, relatively wide bandgaps, relatively large conduction band offset, and/or relatively high saturated electron drift velocity. A major portion of the electrons in the 2DEG may be attributed to polarization in the AlGaN.

A GaN-based HEMT can be formed on a silicon carbide substrate. A GaN channel layer can be on the substrate, and an AlGaN barrier layer can be on the channel layer. A 2DEG can arise in the channel layer adjacent the barrier layer. A source contact and a drain contact can be formed on the channel layer. The conductivity of the 2DEG can be modulated by applying a voltage to a gate that can be formed on the barrier layer between the source contact and the drain contact.

Packaged transistors have been used that include a transistor (e.g., a HEMT) in a metal-based package along with matching components of an input matching circuit and/or an output matching circuit between the package leads and transistor gate and drain pads. The matching components of the input matching circuit and/or an output matching circuit of the package typically are used to match an impedance (e.g., 50 ohms) for a particular frequency (e.g., 3.1 GHZ) or a particular frequency range (e.g., 3.1-3.5 GHZ).

Packaged transistors may be implemented as monolithic microwave integrated circuits (MMIC). A MMIC refers to an integrated circuit that operates on radio and/or microwave frequency signals in which all of the circuitry for a particular function is integrated into a single semiconductor chip. An example MMIC device is a transistor amplifier that includes associated matching circuits, feed networks and the like that are all implemented on a common substrate. MMIC transistor amplifiers typically include a plurality of unit cell HEMT transistors that are connected in parallel.

Packaged transistors also may be implemented with integrated passive device (IPD) components. Typically, the IPD components are mounted on printed circuit board (PCB) based substrates, silicon (Si) based substrates, and/or the like.

### SUMMARY

A three-way Doherty amplifier according to some embodiments includes a three-way power splitter configured to receive an input signal and to output a main signal without a phase shift provided at a main splitter output, a first peak signal with a 90° phase shift provided at a first peak signal output, and a second peak signal with a 180° phase shift provided at a second peak signal output. The three-way Doherty amplifier further includes a main path including a main amplifier, a first input network coupled between the main splitter output and the main amplifier, and a main impedance load on the main amplifier configured to impose a main phase offset of 90°. The three-way Doherty amplifier further includes a first peak path including a first peak amplifier, a second input network coupled between the first peak signal output and the first peak amplifier, and a first peak impedance load on the first peak amplifier configured to impose a first peak phase offset of 90°. The three-way Doherty amplifier further includes a second peak path comprising a second peak amplifier, a third input network coupled between the second peak signal output and the second peak amplifier, and a second peak impedance load on the second peak amplifier. The three-way Doherty amplifier further includes a combining node configured to provide an output load impedance to output the main signal during an average power saturation and a combination of the main signal, the first peak signal, and the second peak signal during a peak power saturation. A first ratio of a gate width of the main amplifier to a first gate width of the first peak amplifier and a second ratio of the gate width of the main amplifier to a second gate width of the second peak amplifier, respectively, are configured to provide a substantially constant load on the main amplifier.

For the main amplifier, a power at the average power may be about the same as the power at the peak power.

The main impedance load may include a main shunt inductor configured to resonate a main drain-source capacitance, Cds, in a frequency band; the first impedance load may include a first shunt inductor configured to resonate a first peak Cds in the frequency band; and the second impedance load may include a second shunt inductor configured to resonate a second peak Cds in the frequency band.

The Doherty combining node may include a resistive load impedance for 1/(1+P1+P2), where P1 represents a number of pairs of fingers of the first peak amplifier normalized to a number of pairs of fingers of the main amplifier and P2 represents a number of pairs of fingers of the second peak amplifier normalized to the number of pairs of fingers of the main amplifier.

The gate width of P1 may be greater than the gate width of the pairs of fingers of the main amplifier and the gate width of P2 may be greater than the gate width of P1.

The first ratio of the gate width of the main amplifier to the first gate width of the first peak amplifier and the second ratio of the gate width of the main amplifier to the second gate width of the second peak amplifier, respectively, may be configured to provide a substantially constant load on the main amplifier based on having a same impedance loading on the main amplifier, the first peak amplifier, and the second peak amplifier to cancel load modulation.

The main impedance load may include a first shunt inductor in series with a first capacitor and a first transmission line or a first lumped equivalent of the first transmission line. The first peak impedance load may include a second shunt inductor in series with a second capacitor and a second transmission line or a second lumped equivalent of the second transmission line. The second peak impedance load may include a third shunt inductor in parallel with a third capacitor.

The first ratio of the gate width of the main amplifier to the first gate width of the first peak amplifier is 1:1 and the second ratio of the gate width of the main amplifier to the second gate width of the second peak amplifier may be 1:2.

A ratio of peak power to average power output from the combining node may be about −6 dB.

The first ratio of the gate width of the main amplifier to the first gate width of the first peak amplifier may be 1:2 and the second ratio of the gate width of the main amplifier to the second gate width of the second peak amplifier may be 1:6.

A ratio of peak power to average power output from the combining node may be about −9.5 dB.

The first ratio of the gate width of the main amplifier to the first gate width of the first peak amplifier may be 1:3 and the second ratio of the gate width of the main amplifier to the second gate width of the second peak amplifier may be 1:12.

A ratio of peak power to average power output from the combining node may be about −12 dB.

The first ratio of the gate width of the main amplifier to the first gate width of the first peak amplifier may be 1:4 and the second ratio of the gate width of the main amplifier to the second gate width of the second peak amplifier may be 1:20.

A ratio of peak power to average power output from the combining node may be about −14 dB.

The main amplifier may be a class AB transistor and the first peak amplifier and the second peak amplifier, respectively, may be class C transistors.

A three-way Doherty amplifier according to some other embodiments includes a three-way power splitter configured to receive an input signal and to output a main signal with a 180° phase shift provided at a main splitter output, a first peak signal with a 90° phase shift provided at a first peak signal output, and a second peak signal without a phase shift provided at a second peak signal output. The three-way Doherty amplifier further includes a main path including a main amplifier, a first input network coupled between the main splitter output and the main amplifier, and a main impedance load on the main amplifier configured to impose a main phase offset of 180°. The three-way Doherty amplifier further includes a first peak path comprising a first peak amplifier, a second input network coupled between the first peak signal output and the first peak amplifier, and a first peak impedance load on the first peak amplifier configured to impose a first peak phase offset of 90°. The three-way Doherty amplifier further includes a second peak path including a second peak amplifier, a third input network coupled between the second peak signal output and the second peak amplifier, and a second peak impedance load on the second peak amplifier to impose a second peak offset of 360°. The three-way Doherty amplifier further includes a combining node configured to provide an output load impedance to output the main signal during an average power saturation and a combination of the main signal, the first peak signal, and the second peak signal during a peak power saturation. A first ratio of a gate width of the main amplifier to a first gate width of the first peak amplifier and a second ratio of the gate width of the main amplifier to a second gate width of the second peak amplifier, respectively, are configured to provide a substantially constant load on the main amplifier.

For the main amplifier, a power at the average power may be about the same as the power at the peak power.

The main impedance load may include a main shunt inductor configured to resonate a main drain-source capacitance, Cds, in a frequency band. The first impedance load may include a first shunt inductor configured to resonate a first peak Cds in the frequency band. The second impedance load may include a second shunt inductor configured to resonate a second peak Cds in the frequency band.

The Doherty combining node may include a resistive load impedance for 1/(1+P1+P2), where P1 represents a number of pairs of fingers of the first peak amplifier normalized to a number of pairs of fingers of the main amplifier and P2 represents a number of pairs of fingers of the second peak amplifier normalized to the number of pairs of fingers of the main amplifier.

The gate width of P1 may be greater than the gate width of the pairs of fingers of the main amplifier and the gate width of P2 may be greater than the gate width of P1.

The first ratio of the gate width of the main amplifier to the first gate width of the first peak amplifier and the second ratio of the gate width of the main amplifier to the second gate width of the second peak amplifier, respectively, may be configured to provide a substantially constant load on the main amplifier based on having a same impedance loading on the main amplifier, the first peak amplifier, and the second peak amplifier to cancel load modulation.

The main impedance load may include a first shunt inductor in series with a first capacitor and a first and second transmission line or a first lumped equivalent of the first and/or second transmission line. The first peak impedance load may include a second shunt inductor in series with a second capacitor and a third transmission line or a third lumped equivalent of the third transmission line. The second peak impedance load may include a fourth shunt inductor in series with a fourth capacitor and a fourth transmission line or a lumped equivalent of the fourth transmission line.

The first ratio of the gate width of the main amplifier to the first gate width of the first peak amplifier may be 1:1 and the second ratio of the gate width of the main amplifier to the second gate width of the second peak amplifier may be 1:2.

A ratio of peak power to average power output from the combining node may be about −6 dB.

The first ratio of the gate width of the main amplifier to the first gate width of the first peak amplifier may be 1:2 and the second ratio of the gate width of the main amplifier to the second gate width of the second peak amplifier may be 1:6.

A ratio of peak power to average power output from the combining node may be about −9.5 dB.

The first ratio of the gate width of the main amplifier to the first gate width of the first peak amplifier may be 1:3 and the second ratio of the gate width of the main amplifier to the second gate width of the second peak amplifier may be 1:12.

A ratio of peak power to average power output from the combining node may be about −12 dB.

The first ratio of the gate width of the main amplifier to the first gate width of the first peak amplifier may be 1:4 and the second ratio of the gate width of the main amplifier to the second gate width of the second peak amplifier may be 1:20.

A ratio of peak power to average power output from the combining node may be about −14 dB.

The main amplifier may be a class AB transistor and the first peak amplifier and the second peak amplifier, respectively, may be class C transistors.

A three-way Doherty amplifier according to yet other embodiments includes a two-way power splitter configured to receive an input signal and to output a first signal with a 90° phase shift provided at a first splitter output, and a second signal without a phase shift provided at a second splitter output. The three-way Doherty amplifier further includes a first path including a main device including a first amplifier and a second amplifier, a first input network coupled between the first splitter signal output and the main device, and a first impedance load on the main device configured to impose a phase offset of 90°. The three-way Doherty amplifier further includes a second path including a third amplifier, a second input network coupled between the second splitter signal output and the third amplifier, and a second peak impedance load on the third amplifier configured to impose a second peak phase offset of 180°. The three-way Doherty amplifier further includes a combining node configured to provide an output load impedance to output a main signal during an average power saturation and a combination of the main signal, and the second signal during a peak power saturation. A first ratio of a gate width of the first amplifier to a first gate width of the second amplifier and a second ratio of the gate width of the first amplifier to a second gate width of the third amplifier, respectively, are configured to provide a substantially constant load on the main device.

For the main device, a power at the average power may be about the same as the power at the peak power.

The first impedance load may include a first shunt inductor configured to resonate a first drain-source capacitance, Cds, and a second Cds in a frequency band. The second impedance load may include a second shunt inductor configured to resonate a third Cds in the frequency band.

The Doherty combining node may include a resistive load impedance for 1/(1+P1+P2), where P1 represents a number of pairs of fingers of the second amplifier normalized to a number of pairs of fingers of the first amplifier and P2 represents a number of pairs of fingers of the third amplifier normalized to the number of pairs of fingers of the first amplifier.

The gate width of P1 may be greater than the gate width of the pairs of fingers of the main amplifier and the gate width of P2 may be greater than the gate width of P1.

The first ratio of the gate width of the first amplifier to the first gate width of the second amplifier and the second ratio of the gate width of the first amplifier to the second gate width of the third amplifier, respectively, may be configured to provide a substantially constant load on the main device based on having a same impedance loading on the first amplifier, the second amplifier, and the third amplifier to cancel load modulation.

The first impedance load may include a first shunt inductor in series with a first capacitor and a first transmission line or a first lumped equivalent of the first transmission line. The second impedance load may include a second shunt inductor in series with a second capacitor and a second transmission line or a second lumped equivalent of the second transmission line.

The first ratio of the gate width of the first amplifier to the first gate width of the second amplifier may be 1:1 and the second ratio of the gate width of the first amplifier to the second gate width of the third amplifier may be 1:2.

A ratio of peak power to average power output from the combining node may be about −6 dB.

The first ratio of the gate width of the first amplifier to the first gate width of the second amplifier may be 1:2 and the second ratio of the gate width of the first amplifier to the second gate width of the third amplifier may be 1:6.

A ratio of peak power to average power output from the combining node may be about −9.5 dB.

The first ratio of the gate width of the first amplifier to the first gate width of the second amplifier may be 1:3 and the second ratio of the gate width of the first amplifier to the second gate width of the third amplifier may be 1:12.

A ratio of peak power to average power output from the combining node may be about −12 dB.

The first ratio of the gate width of the first amplifier to the first gate width of the second amplifier may be 1:4 and the second ratio of the gate width of the first amplifier to the second gate width of the third amplifier may be 1:20.

A ratio of peak power to average power output from the combining node may be about −14 dB.

The first amplifier may be a class AB transistor and the second amplifier and the third amplifier, respectively, may be class C transistors.

A three-way Doherty amplifier according to still other embodiments includes a main path including a main amplifier, a main input network coupled between a main splitter output and the main amplifier, and a main output network coupled between the main amplifier and a combining node. The three-way Doherty amplifier further includes a first peak path including a first peak amplifier, a second input network coupled between a first peak signal output and the first peak amplifier, and a first peak output network coupled between the first peak amplifier and the combining node. The three-way Doherty amplifier further includes a second peak path including a second peak amplifier, a third input network coupled between a second peak signal output and the second peak amplifier, and a second peak output network coupled between the second peak amplifier and the combining node. A first ratio of a gate width of the main amplifier to a first gate width of the first peak amplifier and a second ratio of the gate width of the main amplifier to a second gate width of the second peak amplifier, respectively, are configured to provide a substantially constant load on the main amplifier.

A three-way Doherty amplifier according to other embodiments includes a first path including a main device including a first amplifier and a second amplifier, a first input network coupled between a first splitter signal output and the main device, and a first output network coupled between the main device and a combining node. The three-way Doherty amplifier further includes a second path including a third amplifier, a second input network coupled between a second splitter signal output and the third amplifier, and a second output network coupled between the third amplifier and the combining node. A first ratio of a gate width of the first amplifier to a first gate width of the second amplifier and a second ratio of the gate width of the first amplifier to a second gate width of the third amplifier, respectively, are configured to provide a substantially constant load on the main device.

Additional features, advantages, and aspects of the disclosure may be set forth or apparent from consideration of the following detailed description, drawings, and claims. Moreover, it is to be understood that both the foregoing summary of the disclosure and the following detailed description includes examples and are intended to provide further explanation without limiting the scope of the disclosure as claimed.

### BRIEF DESCRIPTION OF THE DRAWINGS

The accompanying drawings, which are included to provide a further understanding of the disclosure, are incorporated in, and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 is a schematic diagram of a conventional Doherty amplifier.

FIG. 2 is a plot of input power versus Gain for the mean and peak amplifier circuitries of the conventional Doherty amplifier.

FIG. 3 is a schematic diagram of a first example of a three-way Doherty amplifier according to some embodiments.

FIG. 4A is a schematic diagram of operations of the three-way Doherty amplifier of FIG. 3 during a peak power situation according to some embodiments.

FIG. 4B is a schematic diagram of operations of the three-way Doherty amplifier of FIG. 3 during an average power situation according to some embodiments.

FIG. 5 is a schematic diagram of a second example of a three-way Doherty amplifier according to some embodiments.

FIG. 6A is a schematic diagram of operations of the three-way Doherty amplifier of FIG. 5 during a peak power situation according to some embodiments.

FIG. 6B is a schematic diagram of operations of the three-way Doherty amplifier of FIG. 5 during an average power situation according to some embodiments.

FIG. 7 is a schematic diagram of a third example of a three-way Doherty amplifier according to some embodiments.

FIG. 8A is a schematic diagram of operations of the three-way Doherty amplifier of FIG. 7 during a peak power situation according to some embodiments.

FIG. 8B is a schematic diagram of operations of the three-way Doherty amplifier of FIG. 7 during an average power situation according to some embodiments.

FIG. 9A is a schematic diagram of a top view of an example configuration a main transistor and a first peak transistor of the three-way Doherty amplifier of FIG. 7 according to some embodiment.

FIG. 9B is a schematic diagram of operation of the main and first peak amplifier of FIG. 9A in an average power situation according to some embodiments.

FIG. 10 is a plot of total gate width of a main amplifier, a first peak amplifier (P1), and a second peak amplifier (P2) versus the ratio peak/average power for examples of optimum ratios of peak/average power for a three-way Doherty amplifier according to some embodiments of the present disclosure.

FIG. 11 is a schematic illustration of a MMIC amplifier including a HEMT transistor according to some embodiments.

FIGS. 12A and 12B are schematic cross-sectional views illustrating example packages for three-way Doherty amplifiers according to some embodiments.

### DETAILED DESCRIPTION OF THE DISCLOSURE

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element is referred to as being “connected” or “coupled” to another element, it can be directly connected or coupled to the another element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element to another element as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

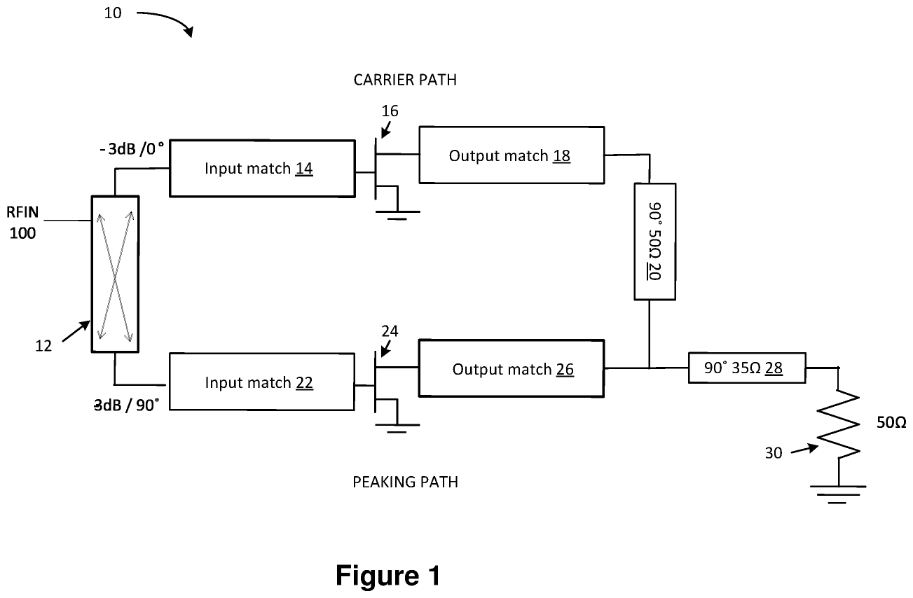

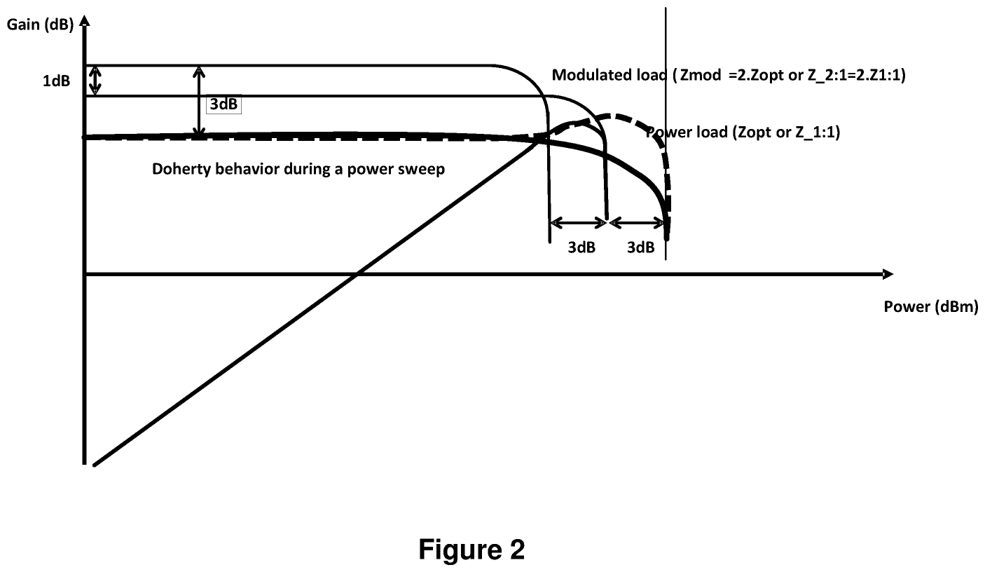

The present disclosure relates to having a substantially constant load on a main amplifier of a three-way Doherty amplifier. Before discussing details of embodiments of the present disclosure, an overview of an example of a conventional Doherty amplifier is provided in association with FIGS. 1 and 2.

Wireless communications signals, for example, can use complex modulation schemes (e.g., orthogonal frequency division multiplexing (OFDM)) having a high peak-to-average power ratio. As a consequence, an amplifier operating at its peak power with its maximum efficiency may be unlikely. A Doherty amplifier, however, may be used to provide dynamic load modulation where the load seen by a “main” amplifier changes as function of the power level in order to enhance efficiency at lower power levels.

An example of a conventional Doherty amplifier uses two amplifiers (also referred to herein as a “two-way Doherty amplifier”). A carrier amplifier (also referred to herein as a “main amplifier”) is included to handle a lower-power region, while a peaking amplifier (also referred to herein as a “peak amplifier”) is included to handle a high-power region. An objective of a Doherty amplifier design is for the carrier amplifier to always be on, while the peaking amplifier is off unless an input RF signal moves into the high-power region. In the high-power region, the peaking amplifier turns on and provides additional amplification to support a higher output power.

RF power amplifiers that can be used in Doherty amplifiers can include classes such as Class A to Class C amplifiers for a controlled current source. Generally, the higher the class of the amplifier, the more efficient is the amplifier, but the less linear it is. While controlled current source amplifiers provide a compromise between linearity and efficiency, a disadvantage can be that maximum efficiency of such amplifiers can drop significantly when input RF power is reduced. One reason for a reduction in RF power can be insufficient linearity. As a consequence of insufficient linearity, in a conventional Doherty amplifier, an objective is to modulate the load seen by the main amplifier (where the load is shared with the peak amplifier) by injecting a current from the peak amplifier, in order to try to provide an optimal efficiency at a given backoff power.

Thus, application of separate RF outputs from the two amplifiers to the load changes the value of the load (or in other words, modulates the load). In the low power region, only the main amplifier is active and delivers power to the load. This mode of operation extends until the main amplifier reaches saturation. Beyond this point, the peaking amplifier starts contributing by injecting current into the common load. This higher power region is characterized by a decrease of the load impedance seen by the main amplifier due to load modulation.

FIG. 1 is a schematic diagram of an example of a conventional two-way Doherty amplifier that includes two amplifier devices 16, 24 (e.g., field effect transistors (FETs) that operate in main and peak power paths, respectively. As illustrated in FIG. 1, a modulated RF input signal RFIN 100 is fed to a power splitter 12, which splits the RF input signal RFIN 100 along a main path and a peak path. In this example, the RF input signal RFIN 100 is split evenly such that the main path and the peak path receive one-half (−3 dB) of the original input power of the RF input signal RFIN 100.

The main path in this example includes a main input match network 14, main transistor 16, and a main output match network 18. The peak path includes a peak input match network 22, peak transistor 24, and a peak output match network 26. The output of the main output match network 18 and the output of the peak output match network 26 are coupled to an output power combining network that includes an impedance inverters 20, 28 and output load 30.

In this example, the split RF input signals that are provided by the power splitter 12 are presented to the main and peak input match networks 14, 22 90° out of phase. In other words, the power splitter imparts a 90° phase shift to the RF input signal RF_{IN} 100 that is provided to the peak path in this example.

The main and peak input match networks 14, 22 can be lumped element networks that are designed so that the RF input signal RF_{IN} that is presented to the input of the peak transistor 24 lags the RF input signal RF_{IN} that is presented to the input of the main transistor 16 by approximately 90°. A lumped element network is one that can include inductors, capacitors, and/or resistors as the primary filtering and phase shifting components. In the illustrated example in FIG. 1, the peak input match network 22 delays the RF input signal RF_{IN} in the peak path by) 90° (−90°, and the main input match network 14 does not advance or delay the RF input signal RF_{IN} in the main path. By delaying the RF input signal RF_{IN} in the peak path by 90°, the RF input signal RF_{IN} that is presented to the input of the peak transistor 24 lags the RF input signal RF_{IN} that is presented to the input of the main transistor 16 by approximately 90°.

Continuing with FIG. 1, the main output match network 18 is coupled between the main transistor 16 and the output combining network 20, 28, 30. Similarly, the peak output match network 16 is coupled between the peak transistor 24 and the combining output network 20, 28, 30. A primary function of the main and peak output match networks 18, 26 is to remove phase shifts provided by the main and peak input networks 14, 22 and provide any phase offsets deemed necessary to try to achieve desired performance metrics. After passing through the main and peak output match networks 18, 26, the amplified RF input signals RF_{IN} from the main and peak paths are presented to the output combining network 20, 28 for a phase alignment that allows the signals to be efficiently combined.

The output network component 20 at the output of output match network 18, in this example, is a quarter-wave (λ/4) transmission line that introduces a 90° phase shift and provides an impedance match of 50Ω. The output network component 28 at the output of output match network 26 is another λ/4 wave transmission line that that introduces a 90° phase shift and provides an impedance match of 35Ω. The output network components 20, 28 provide an impedance inversion at the output of the two-way Doherty amplifier illustrated in FIG. 1. Output network components 20, 28 may be lumped circuit elements in place of the transmission lines.

As discussed herein, in the two-way Doherty amplifier of FIG. 1, for example, load modulation can change the efficiency of amplifiers 16, 24. Without impedance inverters 20, 28, when the two separate RF signals from the main path and the peak path are applied to the same load 30, the value of load 30 is reduced, which may mean that the efficiency of amplifiers 16, 24 is reduced. To try to keep efficiency high, the load 30 and the power may be increased with impedance inverters 20, 28. However, A/4 transmission lines 20, 28 (or their lumped equivalent) may be a bandwidth-limited approach.

Design challenges for Doherty amplifiers can include splitting and recombining an input radio frequency (RF) signal while maintaining time alignment; and turning on the peak amplifier under proper conditions while maintaining linearity. Moreover, modulation techniques can depend on maintaining amplitude and phase conditions of the RF signal. Thus, another objective can include that the combined operation of the main and peak amplifiers is linear.

Linearity is a measure of an amount of distortion of the amplified output signal with respect to the original input signal. When the example two-way Doherty amplifier of FIG. 1 approaches saturation, its gain value can start to compress which can lead to distortion of the output signal. The signal distortion can be characterized in terms of amplitude distortion (“AMAM”) in the gain versus power shapes. AMAM distortion represents the gain compression of the Doherty amplifier and, typically in conventional Doherty amplifiers, the distortion is more impactful at peak power.

FIG. 2 is a schematic diagram that shows AMAM distortion of the example two-way Doherty amplifier of FIG. 1 configured with gallium nitride (GaN) FET transistors as main amplifier 14 and peak amplifier 24. The solid line labeled “Modulated load” shows “ideal” theoretical performance of the two-way Doherty while operating in an average power situation with only the main transistor on. The solid line labelled “Power load” illustrates “ideal” theoretical performance of the two-way Doherty amplifier while operating in a peak power situation with both the main and peak transistors on.

In contrast, the dashed line labelled “Doherty behavior during sweep” shows an example of performance of the two-way Doherty amplifier while operating with an actual main GaN transistor 14 in an average power situation. The second line labelled “Doherty behavior during a power sweep” shows an example of performance of the two-way Doherty amplifier while operating in a peak power situation with the actual main GaN transistor 14 and an actual GaN peak transistor 24 both on. The effect of load modulation can be observed in FIG. 2, where the AMAM distortion of the main path and the peak path are shown by the two lines showing “Doherty behavior during a power sweep” in comparison to the two lines showing theoretical “ideal” behavior.

Limitations of conventional Doherty amplifiers may include: (1) Lack of sufficient linearization. That is, the load modulation leads to distortion in the output signal (e.g., the AMAM shown in FIG. 2). This can be a result of the load modulation being associated with an increase in impedance in the current source plane, as discussed further herein; and (2) Limited RF bandwidth as a result of the modulated impedance, Zmod, suffering from an increased (e.g., degraded) operating point (Q) of a Doherty amplifier with respect to an optimum impedance, Zopt, which limits RF bandwidth.

Certain aspects of the disclosure and their embodiments may provide solutions to these or other challenges. It has been discovered that a configuration of the gate width ratio between a main amplifier, a first peak amplifier, and a second peak amplifier in a three-way Doherty amplifier allows substantially the same loading on each amplifier (e.g., on each transistor) to substantially cancel load modulation (e.g., cancel load modulation completely or limit load modulation). As a consequence, in comparison to conventional Doherty amplifiers, the three-way Doherty amplifier of the present disclosure can have improved linearizability and broader RF bandwidth.

A three-way Doherty amplifier according to some embodiments includes a three-way power splitter configured to receive an input signal and to output a main signal without a phase shift provided at a main splitter output, a first peak signal with a 90° phase shift provided at a first peak signal output, and a second peak signal with a 180° phase shift provided at a second peak signal output. The three-way Doherty amplifier further includes a main path including a main amplifier, a first input network coupled between the main splitter output and the main amplifier, and a main impedance load on the main amplifier configured to impose a main phase offset of 90°. The three-way Doherty amplifier further includes a first peak path including a first peak amplifier, a second input network coupled between the first peak signal output and the first peak amplifier, and a first peak impedance load on the first peak amplifier configured to impose a first peak phase offset of 90°. The three-way Doherty amplifier further includes a second peak path comprising a second peak amplifier, a third input network coupled between the second peak signal output and the second peak amplifier, and a second peak impedance load on the second peak amplifier. The three-way Doherty amplifier further includes a combining node configured to provide an output load impedance to output the main signal during an average power saturation and a combination of the main signal, the first peak signal, and the second peak signal during a peak power saturation. A first ratio of a gate width of the main amplifier to a first gate width of the first peak amplifier and a second ratio of the gate width of the main amplifier to a second gate width of the second peak amplifier, respectively, are configured to provide a substantially constant load on the main amplifier.

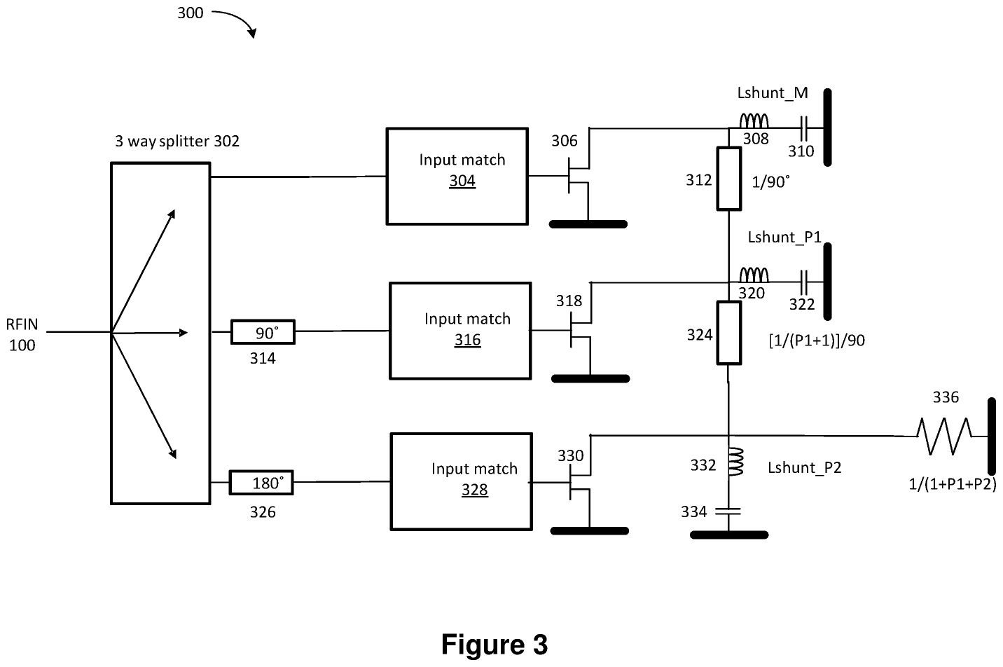

A first example of such a three-way Doherty amplifier 300 is illustrated in FIG. 3. In the three-way Doherty amplifier 300, the amplifiers 306, 318, 330 are transistors having gate width ratios such that the three-way amplifier 300 operates with a substantially constant load. Thus, for the main transistor 306, the power at average power is the same or about the same as the power at peak power.

In FIG. 3, a modulated RF input signal RF_{IN} 100 is fed to a three-way splitter 302, which splits the RF input signal RF_{IN} 100 along three paths: a main path, a first peak path, and a second peak path. In this example, the RF input signal RF_{IN} 100 is evenly split among the main path, the first peak path, and the second peak path.

The main path includes a main input match network 304, a main amplifier 306, and a main output network 308, 310, 312. The main output network includes a shunt inductor 308, a series capacitor 310, and transmission line 312.

The first peak path includes a transmission line 314; a first peak input match network 316; a first peak amplifier 318; and a first peak output network 320, 322, 324. The first peak output network includes a shunt inductor 320, a series capacitor 322 and transmission line 324.

The second peak path includes a transmission line 326, a second peak input match network 328, a second peak amplifier 330, and a second peak output network 332, 334. The second peak output network includes a shunt inductor 332 and a series capacitor 334.

The main input match network 306, transmission line 314, first peak input match network 316, transmission line 326, and second peak input match network 328 can be lumped element networks. As referenced previously, a lumped element network is one that can include inductors, capacitors, and/or resistors as the primary filtering and/or phase shifting components.

In the example in FIG. 3, the transmission line 314 advances the RF input signal in the first peak path by 90°. The transmission line 326 advances the RF input signal from the splitter 302 by 180°. The main output network 308, 310, 312 imposes a main phase offset of 90°. The first peak output network 320, 322, 324 imposes a main phase offset of 90°.

During peak power saturation, all three transistors 306, 318, 330 are on and the outputs of the main, first peak path, and second peak path combine into RLoad 336.

During average power saturation, only the main transistor 306 is on, and transistors 318, 330 are off. As a consequence, the RF signal is provided from the splitter 302 to the main input match network 304, and from output of the main input match network 304 to main transistor 306. The output from the main transistor 306 is provided to the transmission line 312, from the transmission line 312 through the transmission line 318, and into RLoad 336.

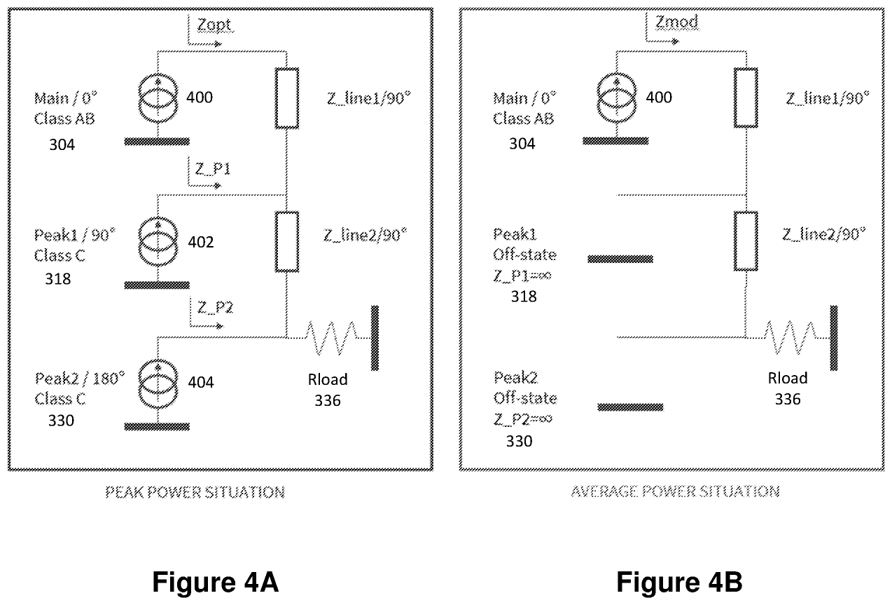

FIGS. 4A and 4B are schematic diagrams illustrating operations of the three-way Doherty amplifier 300 of FIG. 3 during a peak power situation (FIG. 4A) and an average power situation (FIG. 4B).

Referring first to FIG. 4A, during a peak power situation, all three transistors 306, 318, 330 are on. In this example, main transistor 306 is a Class AB transistor, first peak transistor 318 is a Class C transistor, and second peak transistor 330 is a Class C transistor. In the main path, the current source 400 has an impedance Zopt=1. The RF signal from the main transistor 306 is provided to the transmission line 312. Transmission line 312 has an impedance Zline1=1 and imparts a 90° phase shift to the RF signal.

In the first peak path, the current source 402 has an impedance Z_P1=1/P1. The RF signal from the first peak transistor 318 is combined with the signal from the transmission line 312 of the main path into a first combined signal. The first combined signal from the main path and the first peak path are presented to the transmission line 324. Transmission line 324 has an impedance Zline_2+1/(P1+1) and applies a 90° phase shift to the first combined signal.

In the second peak path, current source 404 has an impedance Z_P2=1/P2. The RF signal from the second peak transistor 330 is combined with the first combined signal into a second combined signal into RLoad 336 (which has an impedance 1/(1+P1+P2)).

In FIG. 4B, during an average power situation, main transistor 306 is on, and first and second peak transistors 318, 330 are off. In the main path, the current source 400 has impedance Zmod. The RF signal from the main transistor 306 is provided to the transmission line 312. Transmission line 312 has an impedance Zline1=1 and imparts a 90° phase shift to the RF signal. The RF signal from transmission line 312 is fed into transmission line 324, through the node Zmid. Transmission line 324 has an impedance Zline_2+1/(P1+1) and applies a 90° phase shift to the RF signal. The RF signal from transmission line 324 is provided to RLoad 336 (which has an impedance 1/(1+P1+P2)).

In the off-state, the first peak transistor 318 has an impedance Z_P1=00. Similarly, in the off-state, the second peak transistor 330 has an impedance Z_P2=00.

In some embodiments, transmission lines 312, 328 may be lumped circuit elements in place of the transmission lines.

The following Table summarizes characteristics of the transistors and impedances of the three-way Doherty amplifier of FIGS. 4A and 4B:

| | Class | GW* | Z_current_source** |
|---|---|---|---|
| Main | AB | 1 | 1 |
| Peak1 | C | P1 | 1/P1 |
| Peak2 | C | P2 | 1/P2 |
| | | | RLoad = a/(1 + P1 + P2) |
| | | | Z_Line1 = 1 |
| | | | Z_Line2 + 1?(P1 + 1) |

*GW is normalized to the total gate width of the main transistor 306
**The impedances are normalized to the main impedance Zopt

In the above Table, P1 and P2 can be considered as the number of pairs of fingers of the first and second peak transistors, 318, 330, respectively, normalized to the number of pairs of fingers for the main transistor 306.

For the main amplifier, a power at the average power may be about the same as the power at the peak power.

The main impedance load may include a main shunt inductor configured to resonate a main drain-source capacitance, Cds, in a frequency band; the first impedance load may include a first shunt inductor configured to resonate a first peak Cds in the frequency band; and the second impedance load may include a second shunt inductor configured to resonate a second peak Cds in the frequency band.

The Doherty combining node may include a resistive load impedance for 1/(1+P1+P2), where P1 represents a number of pairs of fingers of the first peak amplifier normalized to a number of pairs of fingers of the main amplifier and P2 represents a number of pairs of fingers of the second peak amplifier normalized to the number of pairs of fingers of the main amplifier.

The gate width of P1 may be greater than the gate width of the pairs of fingers of the main amplifier and the gate width of P2 may be greater than the gate width of P1.

The first ratio of the gate width of the main amplifier to the first gate width of the first peak amplifier and the second ratio of the gate width of the main amplifier to the second gate width of the second peak amplifier, respectively, may be configured to provide a substantially constant load on the main amplifier based on having a same impedance loading on the main amplifier, the first peak amplifier, and the second peak amplifier to cancel load modulation.

The main impedance load may include a first shunt inductor in series with a first capacitor and a first transmission line or a first lumped equivalent of the first transmission line. The first peak impedance load may include a second shunt inductor in series with a second capacitor and a second transmission line or a second lumped equivalent of the second transmission line. The second peak impedance load may include a third shunt inductor in parallel with a third capacitor.

The first ratio of the gate width of the main amplifier to the first gate width of the first peak amplifier is 1:1 and the second ratio of the gate width of the main amplifier to the second gate width of the second peak amplifier may be 1:2.

A ratio of peak power to average power output from the combining node may be about −6 dB.

The first ratio of the gate width of the main amplifier to the first gate width of the first peak amplifier may be 1:2 and the second ratio of the gate width of the main amplifier to the second gate width of the second peak amplifier may be 1:6.

A ratio of peak power to average power output from the combining node may be about −9.5 dB.

The first ratio of the gate width of the main amplifier to the first gate width of the first peak amplifier may be 1:3 and the second ratio of the gate width of the main amplifier to the second gate width of the second peak amplifier may be 1:12.

A ratio of peak power to average power output from the combining node may be about −12 dB.

The first ratio of the gate width of the main amplifier to the first gate width of the first peak amplifier may be 1:4 and the second ratio of the gate width of the main amplifier to the second gate width of the second peak amplifier may be 1:20.

A ratio of peak power to average power output from the combining node may be about −14 dB.

The main amplifier may be a class AB transistor and the first peak amplifier and the second peak amplifier, respectively, may be class C transistors.

A three-way Doherty amplifier according to some other embodiments includes a three-way power splitter configured to receive an input signal and to output a main signal with a 180° phase shift provided at a main splitter output, a first peak signal with a 90° phase shift provided at a first peak signal output, and a second peak signal without a phase shift provided at a second peak signal output. The three-way Doherty amplifier further includes a main path including a main amplifier, a first input network coupled between the main splitter output and the main amplifier, and a main impedance load on the main amplifier configured to impose a main phase offset of 180°. The three-way Doherty amplifier further includes a first peak path comprising a first peak amplifier, a second input network coupled between the first peak signal output and the first peak amplifier, and a first peak impedance load on the first peak amplifier configured to impose a first peak phase offset of 90°. The three-way Doherty amplifier further includes a second peak path including a second peak amplifier, a third input network coupled between the second peak signal output and the second peak amplifier, and a second peak impedance load on the second peak amplifier to impose a second peak offset of 360°. The three-way Doherty amplifier further includes a combining node configured to provide an output load impedance to output the main signal during an average power saturation and a combination of the main signal, the first peak signal, and the second peak signal during a peak power saturation. A first ratio of a gate width of the main amplifier to a first gate width of the first peak amplifier and a second ratio of the gate width of the main amplifier to a second gate width of the second peak amplifier, respectively, are configured to provide a substantially constant load on the main amplifier.

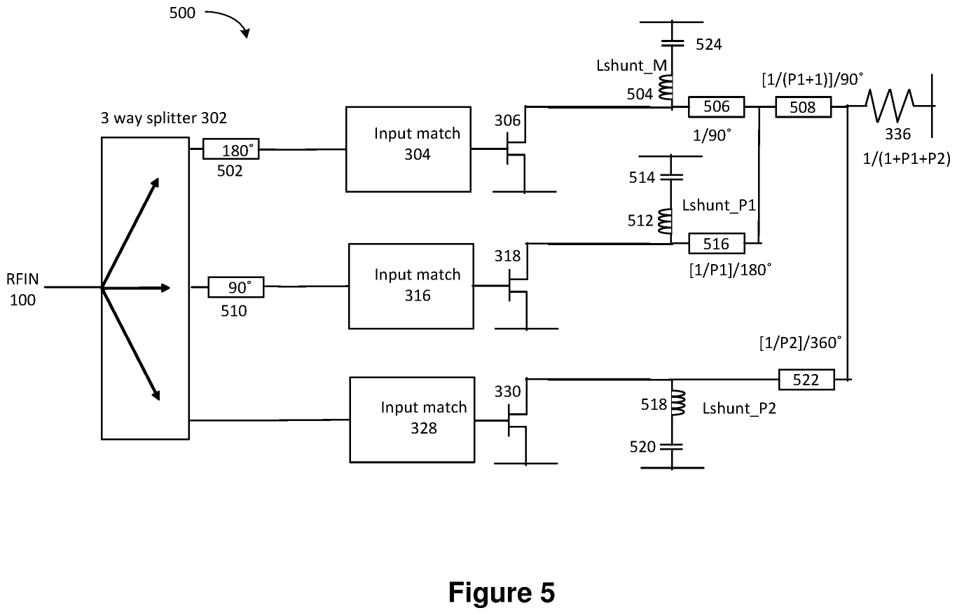

A second example of such a three-way Doherty amplifier 500 is illustrated in FIG. 5. In the three-way Doherty amplifier 500, the amplifiers 306, 318, 330 are transistors having gate width ratios such that the three-way amplifier 500 operates with a substantially constant load. Thus, for the main transistor 306, the power at average power is the same or about the same as the power at peak power.

In FIG. 5, a modulated RF input signal RF_{IN} 100 is fed to a three-way splitter 302, which splits the RF input signal RF_{IN} 100 along three paths: a main path, a first peak path, and a second peak path. In this example, the RF input signal RF_{IN} 100 is evenly split among the main path, the first peak path, and the second peak path.

The main path includes a first transmission line 502, a main input match network 304, a main amplifier 306, and a main output network 504, 506, 508. The main output network includes a shunt inductor 504, a series capacitor 524, transmission line 506, and transmission line 508.

The first peak path includes a second transmission line 510; a first peak input match network 316; a first peak amplifier 318; and a first peak output network 512, 514, 516. The first peak output network include a shunt inductor 512, a series capacitor 514, and transmission line 516.

The second peak path includes a second peak input match network 328, a second peak amplifier 330, and a second peak output network 518, 520, 522. The second peak output network includes a shunt inductor 518, a series capacitor 520, and a transmission line 522.

The first transmission line 502, the main input match network 306, transmission line 506, transmission line 508, transmission line 510, first peak input match network 316, transmission line 516, second peak input match network 328, and transmission line 522 can be lumped element networks. As referenced previously, a lumped element network is one that can include inductors, capacitors, and/or resistors as the primary filtering and/or phase shifting components.

In the example in FIG. 5, the transmission line 502 advances the RF input signal in the main path by 180°, and the transmission lines 506, 508, respectively, impose a main phase offset of 90°. The transmission line 510 advances the RF input signal from the splitter 302 by 90°. The transmission line 508 imposes a main phase offset of 90°; the transmission line 516 imposes a first peak phase offset of 180°; and the transmission line 522 imposes a first peak phase offset of 360°.

During peak power saturation, all three transistors 306, 318, 330 are on and the outputs of the main, first peak path, and second peak path combine into RLoad 336.

During average power saturation, only the main transistor 306 is on, and transistors 318, 330 are off. As a consequence, the RF signal is provided from the splitter 302 to the transmission line 502, from the transmission line 502 to the main input match network 304, and from output of the main input match network 304 to main transistor 306. The output from the main transistor 306 is provided to the transmission line 506. From the transmission line 506, the signal is provided to transmission line 508. From transmission line 508, the signal is provided into the RLoad 336.

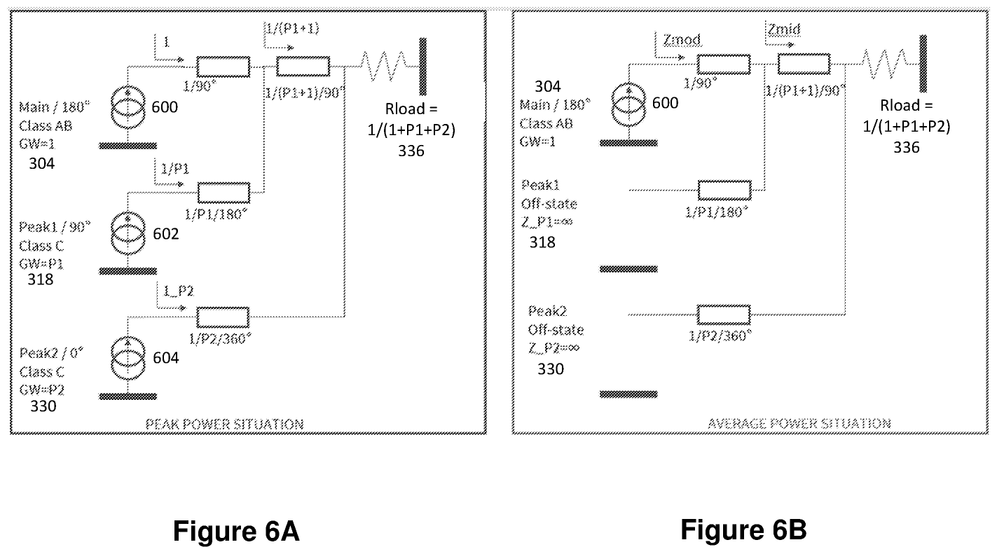

FIGS. 6A and 6B are schematic diagrams illustrating operation of the three-way Doherty amplifier 500 of FIG. 5 during a peak power situation (FIG. 6A) and an average power situation (FIG. 6B).

Referring first to FIG. 6A, during a peak power situation, all three transistors 306, 318, 330 are on. In this example, in the main path, the current source 600 has an impedance Zopt=1. The RF signal from main transistor 306 is fed into transmission line 506 which applies a 90° phase shift.

In the first peak path, the current source 602 has an impedance Z_P1=1/P1. The RF signal from the first peak transistor 318 is provided to transmission line 516 having an impedance ZLine_2 and which applies a 180° phase shift. From the transmission line 516, the signal is fed is combined with the main signal into a first combined signal and provided to transmission line 508. Transmission line 508 has an impedance Z_Line 4=1/(P1+1) and applies a 90 phase shift.

In the second peak path, current source 604 has an impedance Z_P2=1/P2. The RF signal from the second peak transistor 330 is provided to the transmission line 522. Transmission line 522 has an impedance Z_Line 3 and which applies a 360° phase shift. From the transmission line 522, the second signal is combined with the first combined signal into a second combined signal and into RLoad 336 (which has an impedance 1/(1+P1+P2)).

In FIG. 6B, during an average power situation, main transistor 306 is on, and first and second peak transistors 318, 330 are off. In the main path, the current source 600 has impedance Zmod. The RF signal from the main transistor 306 is provided to transmission line 506. Transmission line 506 has an impedance Zline1=1 and imparts a 90° phase shift to the RF signal. The RF signal from transmission line 506 is fed into transmission line 508, through the node Zmid. Transmission line 508 has an impedance Zline_2+1/(P1+1) and imparts a 90° phase shift to the RF signal. The RF signal from transmission line 508 is provided to RLoad 336 (which has an impedance 1/(1+P1+P2)).

In the off-state, the first peak transistor 318 has an impedance Z_P1=∞. Similarly, in the off-state, the second peak transistor 330 has an impedance Z_P2=∞.

In some embodiments, transmission lines 506, 508, 516, and/or 522 may be lumped circuit elements in place of the transmission lines.

For the main amplifier, a power at the average power may be about the same as the power at the peak power.

The main impedance load may include a main shunt inductor configured to resonate a main drain-source capacitance, Cds, in a frequency band. The first impedance load may include a first shunt inductor configured to resonate a first peak Cds in the frequency band. The second impedance load may include a second shunt inductor configured to resonate a second peak Cds in the frequency band.

The Doherty combining node may include a resistive load impedance for 1/(1+P1+P2), where P1 represents a number of pairs of fingers of the first peak amplifier normalized to a number of pairs of fingers of the main amplifier and P2 represents a number of pairs of fingers of the second peak amplifier normalized to the number of pairs of fingers of the main amplifier.

The gate width of P1 may be greater than the gate width of the pairs of fingers of the main amplifier and the gate width of P2 may be greater than the gate width of P1.

The first ratio of the gate width of the main amplifier to the first gate width of the first peak amplifier and the second ratio of the gate width of the main amplifier to the second gate width of the second peak amplifier, respectively, may be configured to provide a substantially constant load on the main amplifier based on having a same impedance loading on the main amplifier, the first peak amplifier, and the second peak amplifier to cancel load modulation.

The main impedance load may include a first shunt inductor in series with a first capacitor and a first and second transmission line or a first lumped equivalent of the first and/or second transmission line. The first peak impedance load may include a second shunt inductor in series with a second capacitor and a third transmission line or a third lumped equivalent of the third transmission line. The second peak impedance load may include a fourth shunt inductor in series with a fourth capacitor and a fourth transmission line or a lumped equivalent of the fourth transmission line.

The first ratio of the gate width of the main amplifier to the first gate width of the first peak amplifier may be 1:1 and the second ratio of the gate width of the main amplifier to the second gate width of the second peak amplifier may be 1:2.

A ratio of peak power to average power output from the combining node may be about −6 dB.

The first ratio of the gate width of the main amplifier to the first gate width of the first peak amplifier may be 1:2 and the second ratio of the gate width of the main amplifier to the second gate width of the second peak amplifier may be 1:6.

A ratio of peak power to average power output from the combining node may be about −9.5 dB.

The first ratio of the gate width of the main amplifier to the first gate width of the first peak amplifier may be 1:3 and the second ratio of the gate width of the main amplifier to the second gate width of the second peak amplifier may be 1:12.

A ratio of peak power to average power output from the combining node may be about −12 dB.

The first ratio of the gate width of the main amplifier to the first gate width of the first peak amplifier may be 1:4 and the second ratio of the gate width of the main amplifier to the second gate width of the second peak amplifier may be 1:20.

A ratio of peak power to average power output from the combining node may be about −14 dB.

The main amplifier may be a class AB transistor and the first peak amplifier and the second peak amplifier, respectively, may be class C transistors.

A three-way Doherty amplifier according to yet other embodiments includes a two-way power splitter configured to receive an input signal and to output a first signal with a 90° phase shift provided at a first splitter output, and a second signal without a phase shift provided at a second splitter output. The three-way Doherty amplifier further includes a first path including a main device including a first amplifier and a second amplifier, a first input network coupled between the first splitter signal output and the main device, and a first impedance load on the main device configured to impose a phase offset of 90°. The three-way Doherty amplifier further includes a second path including a third amplifier, a second input network coupled between the second splitter signal output and the third amplifier, and a second peak impedance load on the third amplifier configured to impose a second peak phase offset of 180°. The three-way Doherty amplifier further includes a combining node configured to provide an output load impedance to output a main signal during an average power saturation and a combination of the main signal, and the second signal during a peak power saturation. A first ratio of a gate width of the first amplifier to a first gate width of the second amplifier and a second ratio of the gate width of the first amplifier to a second gate width of the third amplifier, respectively, are configured to provide a substantially constant load on the main device.

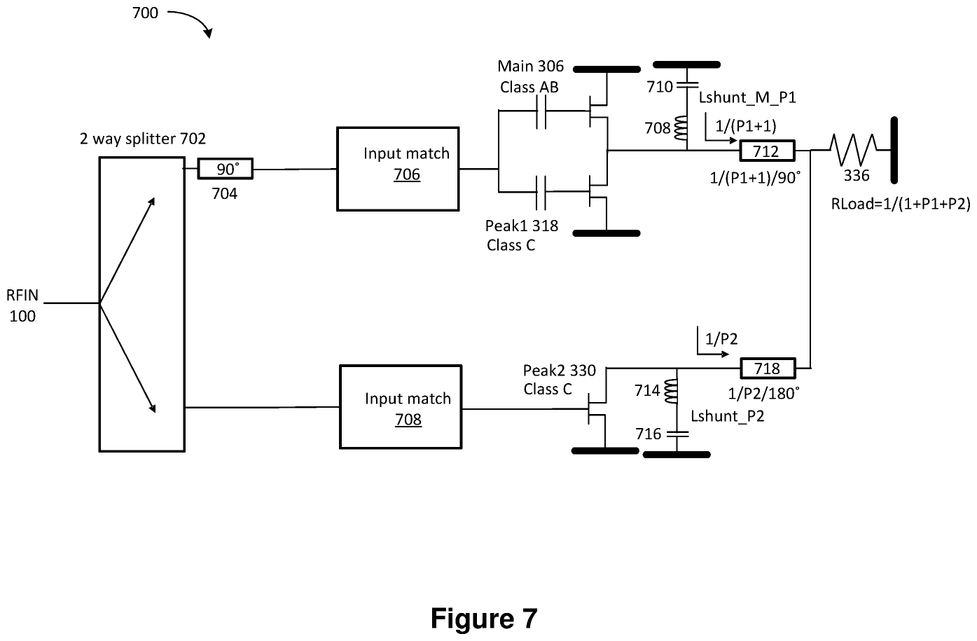

A third example of a such a three-way Doherty amplifier 700 is illustrated in FIG. 7. In the three-way Doherty amplifier 500, the amplifiers 306, 318, 330 are transistors having gate width ratios such that the three-way amplifier 700 operates with a substantially constant load. Thus, for the main transistor 306, the power at average power is the same or about the same as the power at peak power.

The three-way Doherty amplifier 700 includes a “main” device that is configured with two transistors: main transistor 306 and first peak transistor 318; and a second peak transistor 330. In this example, main transistor is a Class AB transistor, first peak transistor 318 is a Class C transistor, and second peak transistor 330 is a Class C transistor. A physical distance between the main transistor 306 and the first peak transistor 318, in this example, is 0°. Thus, in an average power situation when the first peak transistor 318 is off, the first peak transistor 318 appears as an open circuit.

In FIG. 7, a modulated RF input signal RF_{IN} 100 is fed to a two-way splitter 702, which splits the RF input signal RF_{IN} 100 along two paths: a main path and a peak path. In this example, the RF input signal RF_{IN} 100 is evenly split among the main path and the peak path.

The main path includes a first transmission line 704, a main input match network 706, the “main” device including main transistor 306 and first peak transistor 318, and a main output network 708, 710, 712. The main output network includes a shunt inductor 708, a series capacitor 710, and transmission line 712.

The peak path includes a peak input match network 708; second peak transistor 330; and a peak output network 714, 716, 718. The peak path output includes a shunt inductor 714, a series capacitor 716, and a transmission line 718.

The transmission line 704, the main input match network 706, transmission line 712, peak input match network 700, and/or transmission line 718 can be lumped element networks.

In the example in FIG. 7, the transmission line 704 advances the RF input signal in the main path by 90°, and the transmission line 712 imposes a main phase offset of 90°. The transmission line 718 imposes 180° phase offset.

During peak power saturation, all three transistors 306, 318, 330 are on and the outputs of the main and peak path combine into RLoad 336.

During average power saturation, only the main transistor 306 is on, and transistors 318, 330 are off. As a consequence, the RF signal is provided from the splitter 702 to the transmission line 704, from the transmission line 704 to the main input match network 706, and from output of the main input match network 706 to main transistor 306 and the first peak transistor 318. The output from the main and first peak transistors 306, 318 is provided to the transmission line 712. From the transmission line 712, the signal is provided into the RLoad 336.

For the main device, a power at the average power may be about the same as the power at the peak power.

The first impedance load may include a first shunt inductor configured to resonate a first drain-source capacitance, Cds, and a second Cds in a frequency band. The second impedance load may include a second shunt inductor configured to resonate a third Cds in the frequency band.

The Doherty combining node may include a resistive load impedance for 1/(1+P1+P2), where P1 represents a number of pairs of fingers of the second amplifier normalized to a number of pairs of fingers of the first amplifier and P2 represents a number of pairs of fingers of the third amplifier normalized to the number of pairs of fingers of the first amplifier.

The gate width of P1 may be greater than the gate width of the pairs of fingers of the main amplifier and the gate width of P2 may be greater than the gate width of P1.

The first ratio of the gate width of the first amplifier to the first gate width of the second amplifier and the second ratio of the gate width of the first amplifier to the second gate width of the third amplifier, respectively, may be configured to provide a substantially constant load on the main device based on having a same impedance loading on the first amplifier, the second amplifier, and the third amplifier to cancel load modulation.

The first impedance load may include a first shunt inductor in series with a first capacitor and a first transmission line or a first lumped equivalent of the first transmission line. The second impedance load may include a second shunt inductor in series with a second capacitor and a second transmission line or a second lumped equivalent of the second transmission line.

The first ratio of the gate width of the first amplifier to the first gate width of the second amplifier may be 1:1 and the second ratio of the gate width of the first amplifier to the second gate width of the third amplifier may be 1:2.

A ratio of peak power to average power output from the combining node may be about −6 dB.

The first ratio of the gate width of the first amplifier to the first gate width of the second amplifier may be 1:2 and the second ratio of the gate width of the first amplifier to the second gate width of the third amplifier may be 1:6.

A ratio of peak power to average power output from the combining node may be about −9.5 dB.

The first ratio of the gate width of the first amplifier to the first gate width of the second amplifier may be 1:3 and the second ratio of the gate width of the first amplifier to the second gate width of the third amplifier may be 1:12.

A ratio of peak power to average power output from the combining node may be about −12 dB.

The first ratio of the gate width of the first amplifier to the first gate width of the second amplifier may be 1:4 and the second ratio of the gate width of the first amplifier to the second gate width of the third amplifier may be 1:20.

A ratio of peak power to average power output from the combining node may be about −14 dB.

The first amplifier may be a class AB transistor and the second amplifier and the third amplifier, respectively, may be class C transistors.

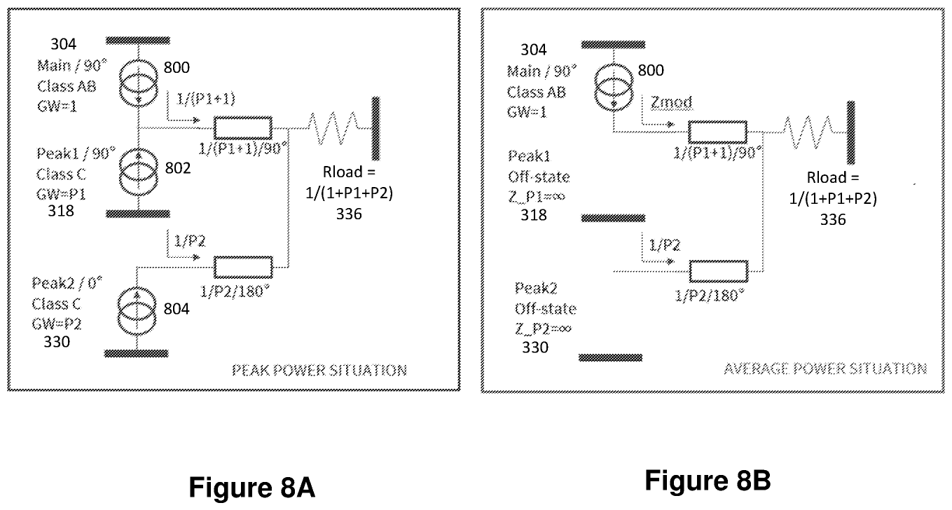

FIGS. 8A and 8B are schematic diagrams illustrating operations of the three-way Doherty amplifier 700 of FIG. 7 during a peak power situation (FIG. 8A) and an average power situation (FIG. 8B).

Referring first to FIG. 8A, during a peak power situation, all three transistors 306, 318, 330 are on. In this example, in the main path, the current sources 800, 802 has an impedanceZ_P1=1/(P1+1). The RF signal from main and first peak transistors 306, 318 is fed into transmission line 712 having an impedance ZLine_1 and which applies a 90° phase shift.

In the peak path, the current source 804 has an impedance Z_P2=1/P2. The RF signal from the second peak transistor 318 is provided to transmission line 718 having an impedance ZLine_2 and which applies a 180° phase shift. From the transmission line 718, the signal is fed is combined with the main path signal into a combined signal. The combined signal is provided into RLoad 336 (which has an impedance 1/(1+P1+P2)).

In FIG. 6B, during an average power situation, main transistor 306 is on, and first and second peak transistors 318, 330 are off. In the main path, the current source 800 has impedance Zmod. The RF signal from the main transistor 306 is provided to transmission line 712. Transmission line 712 has an impedance of 1/(P1+1) and which applies a 90° phase shift to the RF signal. The RF signal from transmission line 712 is provided to RLoad 336 (which has an impedance 1/(1+P1+P2)).

In the off-state, the first peak transistor 318 has an impedance Z_P1=∞. Similarly, in the off-state, the second peak transistor 330 has an impedance Z_P2=∞.

In some embodiments, transmission lines 704, 712, and/or 718 may be lumped circuit elements in place of the transmission lines.

In some embodiments, a first impedance load comprises a first shunt inductor configured to resonate a first drain-source capacitance, Cds, and a second Cds in a frequency band, and a second impedance load comprises a second third shunt inductor configured to resonate a third Cds in the frequency band.

The following Table summarizes characteristics of the transistors and impedances of the three-way Doherty amplifier of FIGS. 4A, 4B, 6A, 6B, 8A, and 8B:

| | Class | GW* | Z_current_source** |
|---|---|---|---|
| Main | AB | 1 | 1 |
| Peak1 | C | P1 | 1/P1 |
| Peak2 | C | P2 | 1/P2 |
| | | | RLoad = a/(1 + P1 + P2) |

*GW is normalized to the total gate width of the main transistor 306
**The impedances are normalized to the main impedance Zopt

In the above Table, P1 and P2 can be considered as the number of pairs of fingers of the transistors, 318, 330, respectively, normalized to the number of pairs of fingers for the main transistor 306.

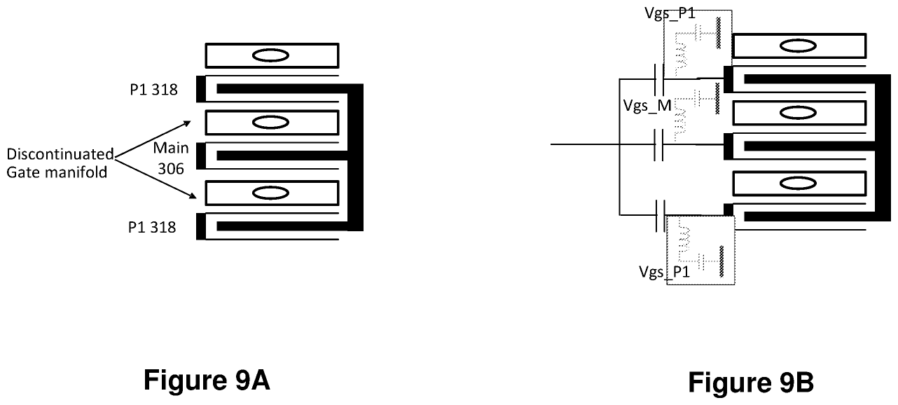

FIG. 9A is a schematic diagram of a top view of an example configuration of main transistor 306 and first peak transistor 318 of three-way Doherty amplifier 700 of FIG. 7 configured with a gate width ratio of 1/2/6 (as discussed further herein). More specifically,

FIG. 9A illustrates an example of a physical distance of 0° between the main transistor 306 and the first peak transistor 318. FIG. 9B illustrates operation of main transistor 306 and first peak transistor 318 in an average power situation where the first peak transistor 318 is off and appears as an open circuit.

As discussed herein, for the main transistor 306, the power at average power is the same or about the same as the power at peak power. As a consequence, the peak to average ratio of the three-way Doherty amplifier of examples of the present disclosure is driven by:
Power at average power from only the main amplifier 306 is 1 (normalized)
Power at peak power from all three transistors 306, 318, 330 is 1+P1+P2.

As shown herein, two impedances load the main transistor 306: Zopt during peak power operation when all three transistors 306, 318, 328 are on; and Zmod during average power operation when only main transistor 306 is on and transistors 318, 330 are off. No load modulation means that Zmod for the main transistor 306 is equal to 1. The gate width ratio for P1 and P2 that can cancel load modulation (i.e., Zmod=1) can be determined as follows.

Resistance of resistor 336 is known and is equal to 1/(P1+P2+1).

Impedance of transmission line 324 (Z_line2) is known and is equal to 1/(P1+1).

From RLoad and Z_line2, Zmid of three-way Doherty amplifier 300 can be calculated, where Zmid=Z_line2²/RLoad=(1+P1+P2)/(1+P1)².

Impedance of transmission line 312 (Z_line1) is known. Thus, Zmod can be calculated, where Zmod=Z_line1²/Zmid=(1+P1)²/(1+P1+P2).

As previously discussed, no load modulation means Zmod=1, which means Zmod=(1+P1)²/(1+P1+P2)=1. This simplifies into P1²+P1−P2=0, which is a second order polynomial equation. The second order polynomial equation has solutions P1=(−1+/−√Δ)/2 with Δ=1+4·P2. P1 and P2 each should be a positive integer number. Thus, there is a range of solutions from A values that are odd square values: 9, 25, 49, 81 . . . .

Solving the equation P1=(−1+/−√Δ)/2 with at least these Δ (delta) values results in the following transistor gate width ratii:

| | | | | |
|---|---|---|---|---|
| Δ | 9 | 25 | 49 | 81 |
| Main transistor | 1 | 1 | 1 | 1 |
| 306 | | | | |
| First peak transistor | 1 | 2 | 3 | 4 |
| 318 | | | | |
| Second peak transistor | 2 | 6 | 12 | 20 |

As discussed herein, limitations of conventional Doherty amplifiers may include (1) that the load modulation is associated with an increase in impedance in the current source plane, that is Zmod=(1+asymmetry). Zopt; where Zopt and Zmod are the impedances loading the main amplifier 16 and the asymmetry is the power ratio between the carrier and the peaking path (P_Peak/P_Main (Gain in dB)); and (2) limited RF bandwidth as a result of the modulated impedance, Zmod, suffering from an increased (e.g., degraded) operating point (Q) of the device with respect to Zopt, which limits RF bandwidth. This is a result of the output impedance of a FET is a R//C network; and its Q@f0=R.C.π.f0.

In contrast, as discussed herein, the three-way Doherty amplifier of the present allows substantially the same loading on each amplifier to substantially cancel load modulation. As a consequence, in comparison to conventional Doherty amplifiers, the three-way Doherty amplifier of the present disclosure can have improved linearizability and broader RF bandwidth.

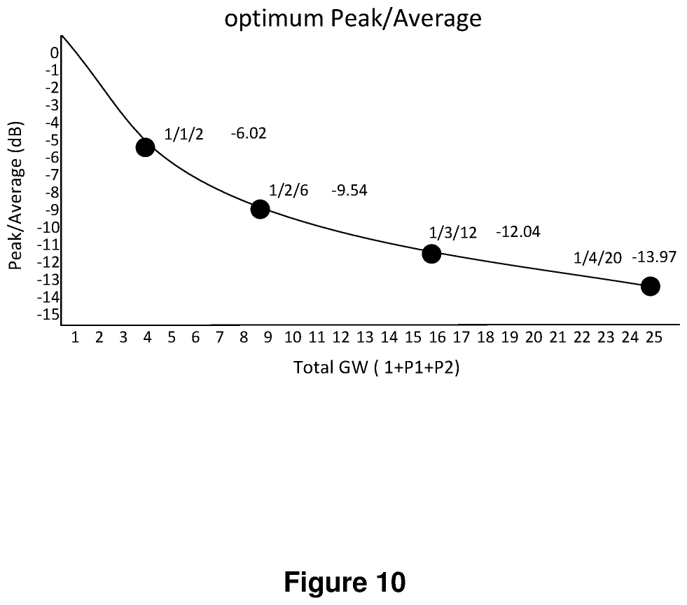

FIG. 10 is a plot of optimum Peak to Average power in dB for a three-way Doherty amplifier versus total gate width of the main transistor, first peak transistor, and second peak transistor of examples herein.

As shown in FIG. 10, when the gate width ratio of the main transistor to the first peak transistor and to the second peak transistor is 1/1/2 (that is, a total gate width (GW) of 4 for (1+P1+P2)), the three-way Doherty amplifier has an optimum peak/average power of-6.02 dB (also referred to as about 6 dB backoff). Such a three-way Doherty amplifier can be useful, for example, for handling RF signals for satellite communications, radar, military communications, portable devices (such as smart phones), WiFi, the Internet of Things (IoT), etc.

When the gate width ratio of the main transistor to the first peak transistor and to the second peak transistor is 1/2/6 (that is, a total gate width (GW) of 9 for (1+P1+P2)), the three-way Doherty amplifier has an optimum peak/average power of −9.54 dB (also referred to as about 9 dB backoff). Such a three-way Doherty amplifier can be useful, for example, for handling RF signals in cellular infrastructures using 4G, 5G, 6G, etc.

When the gate width ratio of the main transistor to the first peak transistor and to the second peak transistor is Jan. 3, 2012 (that is, a total gate width (GW) of 16 for (1+P1+P2)), the three-way Doherty amplifier has an optimum peak/average power of −12.04 dB (also referred to as about 12 dB backoff). Such a three-way Doherty amplifier can be useful, for example, for handling RF signals in cellular infrastructures using 4G, 5G, 6G, etc. for reduced traffic situations.

Still referring to FIG. 10, when the gate width ratio of the main transistor to the first peak transistor and to the second peak transistor is 1/4/20 (that is, a total gate width (GW) of 25 for (1+P1+P2)), the three-way Doherty amplifier has an optimum peak/average power of −13.97 dB (also referred to as about 14 dB backoff). Such a three-way Doherty amplifier can be useful, for example, for handling RF signals in cellular infrastructures using 4G, 5G, 6G, etc. for reduced traffic situations.

In yet other embodiments, a three-way Doherty amplifier includes a main path including a main amplifier, a main input network coupled between a main splitter output and the main amplifier, and a main output network coupled between the main amplifier and a combining node. The three-way Doherty amplifier further includes a first peak path including a first peak amplifier, a second input network coupled between a first peak signal output and the first peak amplifier, and a first peak output network coupled between the first peak amplifier and the combining node. The three-way Doherty amplifier further includes a second peak path including a second peak amplifier, a third input network coupled between a second peak signal output and the second peak amplifier, and a second peak output network coupled between the second peak amplifier and the combining node. A first ratio of a gate width of the main amplifier to a first gate width of the first peak amplifier and a second ratio of the gate width of the main amplifier to a second gate width of the second peak amplifier, respectively, are configured to provide a substantially constant load on the main amplifier.

A three-way Doherty amplifier according to other embodiments includes a first path including a main device including a first amplifier and a second amplifier, a first input network coupled between a first splitter signal output and the main device, and a first output network coupled between the main device and a combining node. The three-way Doherty amplifier further includes a second path including a third amplifier, a second input network coupled between a second splitter signal output and the third amplifier, and a second output network coupled between the third amplifier and the combining node. A first ratio of a gate width of the first amplifier to a first gate width of the second amplifier and a second ratio of the gate width of the first amplifier to a second gate width of the third amplifier, respectively, are configured to provide a substantially constant load on the main device.

In one non-limiting example, the three-way Doherty amplifier 300 is a multiple-input and multiple output (MIMO) Doherty amplifier having a main transistor with four fingers, a first peak transistor with eight fingers, and a second peak transistor with twenty-four fingers, for a total of 36 fingers. The unit gate width is 420 μm. The three-way Doherty 300 amplifier is implemented for an average power of 10 W (40 dBm), a peak power of 49 W (49.5 dBm), and a unit gate width of 420 μm. The resulting three-way Doherty amplifier 300 has the following values:

| | | | Tuning Power | | | |
|---|---|---|---|---|---|---|
| | No. | GW | density | Power | Power | Zopt |
| | Fingers | (mm) | (W/mm) | (W) | (dBm) | (ohms) |
| Main | 4 | 1.68 | 5.95 | 10.00 | 40.00 | 98.81 |
| P1 | 8 | 3.36 | 5.95 | 19.99 | 43.01 | 49.40 |
| P2 | 24 | 10.08 | 5.95 | 59.98 | 47.78 | 16.47 |
| TOTAL | 36 | 15.12 | | 89.964 | 49.54 | |
| Z_Line1 | 98.80 | | Line from | | | |
| | | | Main | | | |
| | | | Transistor | | | |
| Z_Line2 | 32.93 | | Line from First | | | |
| | | | Peak Path | | | |
| RLoad | 10.97 | | | | | |

In another non-limiting example, the three-way Doherty amplifier 500 is a MIMO Doherty amplifier having a main transistor with four fingers, a first peak transistor with eight fingers, and a second peak transistor with twenty-four fingers, for a total of 36 fingers. The unit gate width is 420 μm. The three-way Doherty amplifier 500 is implemented for an average power of 10 W (40 dBm), a peak power of 49 W (49.5 dBm), and a unit gate width of 420 μm. The resulting three-way Doherty amplifier 500 has the following values:

| | | | Tuning Power | | | |
|---|---|---|---|---|---|---|
| | No. | GW | density | Power | Power | Zopt |
| | Fingers | (mm) | (W/mm) | (W) | (dBm) | (ohms) |
| Main | 4 | 1.68 | 5.95 | 10.00 | 40.00 | 98.81 |
| P1 | 8 | 3.36 | 5.95 | 19.99 | 43.01 | 49.40 |
| P2 | 24 | 10.08 | 5.95 | 59.98 | 47.78 | 16.47 |
| TOTAL | 36 | 15.12 | | 89.964 | 49.54 | |
| Z_Line1 | 98.80 | | Line from | | | |
| | | | Main | | | |
| | | | Transistor | | | |
| Z_Line2 | 49.40 | | Line from | | | |
| | | | First Peak | | | |
| | | | Transistor | | | |
| Z_Line3 | 16.47 | | Line from | | | |
| | | | Second Peak | | | |
| | | | Transistor | | | |
| Z_Line4 | 32.94 | | Line to RLoad | | | |
| RLoad | 10.97 | | | | | |

In a further non-limiting example, the three-way Doherty amplifier 700 is a MIMO Doherty amplifier having a main transistor with four fingers, a first peak transistor with eight fingers, and a second peak transistor with twenty-four fingers, for a total of 36 fingers. The unit gate width is 420 μm. The three-way Doherty amplifier 700 is implemented for an average power of 10 W (40 dBm), a peak power of 49 W (49.5 dBm), and a unit gate width of 420 μm. The resulting three-way Doherty amplifier 700 has the following values:

| | | | Tuning Power | | | |
|---|---|---|---|---|---|---|
| | No. | GW | density | Power | Power | Zopt |
| | Fingers | (mm) | (W/mm) | (W) | (dBm) | (ohms) |
| Main | 4 | 1.68 | 5.95 | 10.00 | 40.00 | 32.94 |
| P1 | 8 | 3.36 | 5.95 | 19.99 | 43.01 | |
| P2 | 24 | 10.08 | 5.95 | 59.98 | 47.78 | 16.47 |
| TOTAL | 36 | 15.12 | | 89.964 | 49.54 | |
| Z_Line1 | 32.94 | | Line from | | | |
| | | | Main | | | |
| | | | Transistor + | | | |
| | | | First Peak | | | |
| | | | Transistor | | | |
| Z_Line2 | 16.47 | | Line from | | | |
| | | | Second Peak | | | |
| | | | Transistor | | | |
| RLoad | 10.97 | | | | | |

While examples herein of three-way Doherty amplifiers 300, 500 have been discussed with respect to certain gate width ratios, the present disclosure is not so limited and includes other gate width ratios that result in cancelled or limited load modulation. Limited modulation includes values of Zmod less than 2. The following Table includes further non-limiting examples for three-way Doherty amplifiers 300, 500:

| Main | Peak1 | Peak2 | Zline1 | Zline2 | Zload | Zmid | Zmod | Ppeak | Pavg | Peak/Avg |
|---|---|---|---|---|---|---|---|---|---|---|
| 1 | 1 | 1 | 1 | 0.50 | 0.33 | 0.75 | 1.33 | 3 | 0.75 | 6.02 |
| 1 | 2 | 2 | 1 | 0.33 | 0.20 | 0.56 | 1.80 | 5 | 0.56 | 9.54 |
| 1 | 2 | 3 | 1 | 0.33 | 0.17 | 0.67 | 1.50 | 6 | 0.67 | 9.54 |
| 1 | 2 | 5 | 1 | 0.33 | 0.13 | 0.89 | 1.13 | 8 | 0.89 | 9.54 |
| 1 | 3 | 4 | 1 | 0.25 | 0.13 | 0.50 | 2.00 | 8 | 0.50 | 12.04 |
| 1 | 3 | 5 | 1 | 0.25 | 0.11 | 0.56 | 1.78 | 9 | 0.56 | 12.04 |
| 1 | 3 | 6 | 1 | 0.25 | 0.10 | 0.63 | 1.60 | 10 | 0.63 | 12.04 |
| 1 | 3 | 7 | 1 | 0.25 | 0.09 | 0.69 | 1.45 | 11 | 0.69 | 12.04 |
| 1 | 3 | 8 | 1 | 0.25 | 0.08 | 0.75 | 1.33 | 12 | 0.75 | 12.04 |
| 1 | 3 | 9 | 1 | 0.25 | 0.08 | 0.81 | 1.23 | 13 | 0.81 | 12.04 |
| 1 | 3 | 10 | 1 | 0.25 | 0.07 | 0.88 | 1.14 | 14 | 0.88 | 12.04 |
| 1 | 3 | 11 | 1 | 0.25 | 0.07 | 0.94 | 1.07 | 15 | 0.94 | 12.04 |
| 1 | 4 | 7 | 1 | 0.20 | 0.08 | 0.48 | 2.08 | 12 | 0.48 | 13.98 |
| 1 | 4 | 8 | 1 | 0.20 | 0.08 | 0.52 | 1.92 | 13 | 0.52 | 13.98 |

Further, while examples herein of three-way Doherty amplifier 700 have been discussed with respect to certain gate width ratios, the present disclosure is not so limited and includes other gate width ratios that result in cancelled or limited load modulation. The following Table includes further non-limiting examples for three-way Doherty amplifier 700:

| Main | Peak1 | Peak2 | Zline1 | Zload | Zmod | Ppeak | Pavg | Peak/Avg |
|---|---|---|---|---|---|---|---|---|
| 1 | 1 | 2 | 0.50 | 0.25 | 1.00 | 4 | 1.00 | 6.02 |
| 1 | 1 | 3 | 0.50 | 0.20 | 1.25 | 5 | 0.80 | 7.96 |
| 1 | 2 | 4 | 0.50 | 0.17 | 1.50 | 6 | 0.67 | 9.54 |
| 1 | 2 | 6 | 0.33 | 0.11 | 1.00 | 9 | 1.00 | 9.54 |
| 1 | 3 | 12 | 0.25 | 0.06 | 1.00 | 16 | 1.00 | 12.04 |
| 1 | 3 | 13 | 0.25 | 0.06 | 1.06 | 17 | 0.94 | 12.57 |
| 1 | 3 | 14 | 0.25 | 0.06 | 1.13 | 18 | 0.89 | 13.06 |
| 1 | 3 | 15 | 0.25 | 0.05 | 1.19 | 19 | 0.84 | 13.53 |
| 1 | 3 | 16 | 0.25 | 0.05 | 1.25 | 20 | 0.80 | 13.98 |
| 1 | 3 | 17 | 0.25 | 0.05 | 1.31 | 21 | 0.76 | 14.40 |
| 1 | 3 | 18 | 0.25 | 0.05 | 1.38 | 22 | 0.73 | 14.81 |
| 1 | 3 | 19 | 0.25 | 0.04 | 1.44 | 23 | 0.70 | 15.19 |
| 1 | 3 | 20 | 0.25 | 0.04 | 1.50 | 24 | 0.67 | 15.56 |
| 1 | 3 | 21 | 0.25 | 0.04 | 1.56 | 25 | 0.64 | 15.92 |
| 1 | 3 | 22 | 0.25 | 0.04 | 1.63 | 26 | 0.62 | 16.26 |
| 1 | 4 | 20 | 0.20 | 0.04 | 1.00 | 25 | 1.00 | 13.98 |

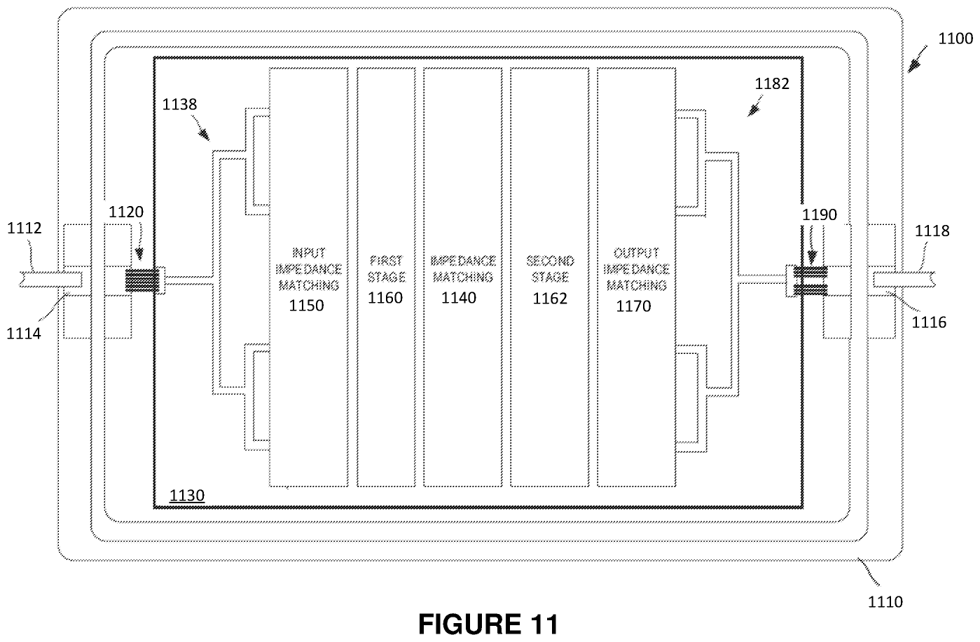

RF transistor amplifiers incorporating transistor devices described herein can be used in standalone RF transistor amplifiers and/or in multiple RF transistor amplifiers. Examples of how the RF transistor amplifiers according to some embodiments may be used in applications that include multiple amplifiers will be discussed with reference to FIGS. 11A-11C.

Referring to FIG. 11A, an RF transistor amplifier 1000A is schematically illustrated that includes a pre-amplifier 1010 and a main amplifier 1030 that are electrically connected in series. As shown in FIG. 11A, RF transistor amplifier 1000A includes an RF input 1001, the pre-amplifier 1010, an inter-stage impedance matching network 1020, the main amplifier 1030, and an RF output 1002. The inter-stage impedance matching network 1020 may include, for example, inductors and/or capacitors arranged in any appropriate configuration in order to form a circuit that improves the impedance match between the output of pre-amplifier 1010 and the input of main amplifier 1030. While not shown in FIG. 11A, RF transistor amplifier 1000A may further include an input matching network that is interposed between RF input 1001 and pre-amplifier 1010, and/or an output matching network that is interposed between the main amplifier 1030 and the RF output 1002. The RF transistor amplifiers according to embodiments may be used to implement either or both of the pre-amplifier 1010 and the main amplifier 1030.

Referring to FIG. 8B, an RF transistor amplifier 1000B is schematically illustrated that includes an RF input 1001, a pair of pre-amplifiers 1010-1, 1010-2, a pair of inter-stage impedance matching networks 1020-1, 1020-2, a pair of main amplifiers 1030-1, 1030-2, and an RF output 1002. A splitter 1003 and a combiner 1004 are also provided. Pre-amplifier 1010-1 and main amplifier 1030-1 (which are electrically connected in series) are arranged electrically in parallel with pre-amplifier 1010-2 and main amplifier 1030-2 (which are electrically connected in series). As with the RF transistor amplifier 1000A of FIG. 9A, RF transistor amplifier 1000B may further include an input matching network that is interposed between RF input 1001 and pre-amplifiers 1010-1, 1010-2, and/or an output matching network that is interposed between the main amplifiers 1030-1, 1030-2 and the RF output 1002.

The RF transistor amplifiers according to embodiments may be formed as discrete devices, or may be formed as part of a Monolithic Microwave Integrated Circuit (MMIC). A MMIC refers to an integrated circuit that operates on radio and/or microwave frequency signals in which all of the circuitry for a particular function is integrated into a single semiconductor chip. An example MMIC device is a transistor amplifier that includes associated matching circuits, feed networks and the like that are all implemented on a common substrate. MMIC transistor amplifiers typically include a plurality of unit cell HEMT transistors that are connected in parallel.

FIG. 11 is a plan view of a MMIC RF transistor amplifier 1100. As shown in FIG. 11, the MMIC RF transistor amplifier 1100 includes an integrated circuit chip 1130 that is contained within a package 1110. The package 1110 may comprise a protective housing that surrounds and protects the integrated circuit chip 1130. The package 1110 may be formed of, for example, a ceramic material.

The package 1110 includes an input lead 1112 and an output lead 1118. The input lead 1112 may be mounted to an input lead pad 1114 by, for example, soldering. One or more input bond wires 1120 may electrically connect the input lead pad 1114 to an input bond pad on the integrated circuit chip 1130. The integrated circuit chip 1130 includes an input feed network 1138, an input impedance matching network 1150, a first RF transistor amplifier stage 1160, an intermediate impedance matching network 1140, a second RF transistor amplifier stage 1162, an output impedance matching stage 1170, and an output feed network 1182. In accordance with embodiments discussed herein, although not shown in FIG. 11, the integrated circuit chip 1130 can include a second intermediate impedance matching circuit, a third RF transistor amplifier stage, and an output impedance matching network to combine signals from the three RF transistors.

The package 1110 further includes an output lead 1118 that is connected to an output lead pad 1116 by, for example, soldering. One or more output bond wires 1190 may electrically connect the output lead pad 1116 to an output bond pad on the integrated circuit chip 1130. The first RF transistor amplifier stage 1160, the second RF transistor amplifier stage 1162, and/or the third RF transistor amplifiers stage may be implemented using any of the RF transistor amplifiers according to embodiments of the present inventive concepts.

The RF transistor amplifiers according to embodiments of the present inventive concepts may be designed to operate in a wide variety of different frequency bands. In some embodiments, these RF transistor amplifier dies may be configured to operate in at least one of the 0.6-2.7 GHZ, 3.4-4.2 GHz, 5.1-5.8 GHZ, 12-18 GHz, 18-27 GHZ, 27-40 GHz or 40-75 GHz frequency bands or sub-portions thereof. The techniques according to embodiments of the present inventive concepts may be particularly advantageous for RF transistor amplifiers that operate at frequencies of 10 GHz and higher.

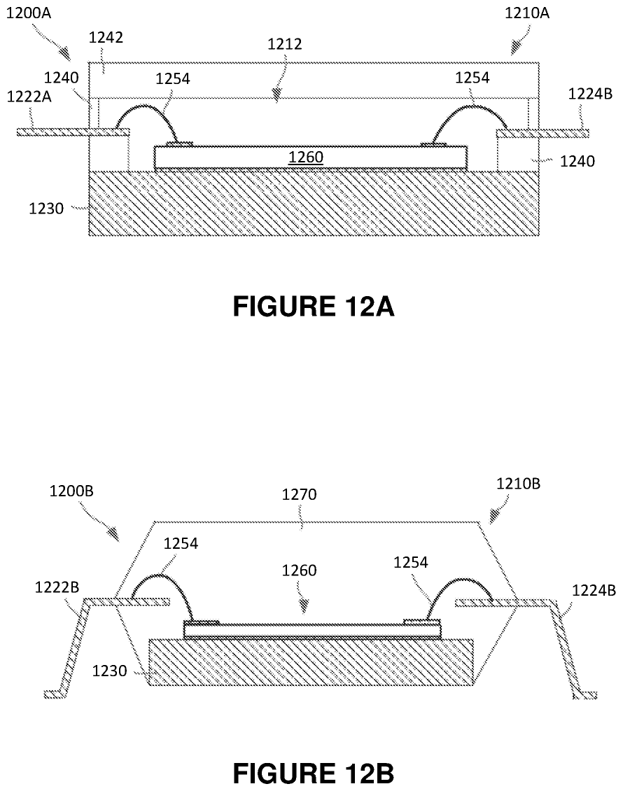

FIGS. 12A and 12B are schematic cross-sectional views illustrating several example ways that that the RF transistor amplifier dies according to embodiments of the present inventive concepts may be packaged to provide packaged RF transistor amplifiers 1200A and 1200B, respectively.

FIG. 12A is a schematic side view of a packaged Group III nitride-based RF transistor amplifier circuit 1200A. As shown in FIG. 12A, packaged RF transistor amplifier circuit 1200A includes a three-way Doherty amplifier circuit 1260 packaged in an open cavity package 1210A. The package 1210A includes metal gate leads 1222A, metal drain leads 1224A, a metal submount 1230, sidewalls 1240 and a lid 1242.

The submount 1230 may include materials configured to assist with the thermal management of the package 1200A. For example, the submount 1230 may include copper and/or molybdenum. In some embodiments, the submount 1230 may be composed of multiple layers and/or contain vias/interconnects. In an example embodiment, the submount 1230 may be a multilayer copper/molybdenum/copper metal flange that comprises a core molybdenum layer with copper cladding layers on either major surface thereof. In some embodiments, the submount 1230 may include a metal heat sink that is part of a lead frame or metal slug. The sidewalls 1240 and/or lid 1242 may be formed of or include an insulating material in some embodiments. For example, the sidewalls 1240 and/or lid 1242 may be formed of or include ceramic materials.

In some embodiments, the sidewalls 1240 and/or lid 1242 may be formed of, for example, Al2O3. The lid 1242 may be glued to the sidewalls 1240 using an epoxy glue. The sidewalls 1240 may be attached to the submount 1230 via, for example, braising. The gate leads 1222A and the drain leads 1224A may be configured to extend through the sidewalls 1240, though embodiments of the present inventive concepts are not limited thereto.

The three-way Doherty amplifier circuit 1260 is mounted on the upper surface of the metal submount 1230 in an air-filled cavity 1212 defined by the metal submount 1230, the ceramic sidewalls 1240 and the ceramic lid 1242. The gate and drain terminals of three-way Doherty amplifier circuit 1260 may be on the top side of the structure, while the source terminals are on the bottom side of the structure.

The gate leads 1222A may be connected to the gate terminals of the three RF transistor amplifiers of circuit 1360 by one or more bond wires 1254. Similarly, the drain leads 1224A may be connected to the drain terminals of the three RF transistor amplifiers of circuit 1360 one or more bond wires 1254. The source terminals may be mounted on the metal submount 1230 using, for example, a conductive die attach material (not shown). The metal submount 1230 may provide the electrical connection to the source terminals 1226 and may also serve as a heat dissipation structure that dissipates heat that is generated in the three-way Doherty amplifier circuit 1260.

The heat is primarily generated in the upper portion of the three-way Doherty amplifier circuit 1260 where relatively high current densities are generated in, for example, the channel regions of the unit cell transistors. This heat may be transferred though source vias (not shown) and the semiconductor layer structure of the device to the source terminals and then to the metal submount 1230.

FIG. 12B is a schematic side view of another packaged Group III nitride based RF three-way Doherty amplifier 1200B. RF transistor amplifier 1200B differs from RF transistor amplifier 1200A in that it includes a different package 1210B. The package 1210B includes a metal submount 1230, as well as metal gate and drain leads 1222B, 1224B. RF transistor amplifier 1200B also includes a plastic overmold 1270 that at least partially surrounds the three-way Doherty amplifier circuit 1260, the leads 1222B, 1224B, and the metal submount 1230.

Many variations of the features of the above embodiments are possible. Transistor structures with features that may be used in embodiments of the present invention are disclosed in the following commonly assigned publications, the contents of each of which are fully incorporated by reference herein in their entirety: U.S. Pat. No. 6,849,882 to Chavarkar et al. and entitled “Group-Ill Nitride Based High Electron Mobility Transistor (HEMT) With Barrier/Spacer Layer”; U.S. Pat. No. 7,230,284 to Parikh et al. and entitled “Insulating Gate AlGaN/GaN HEMT”; U.S. Pat. No. 7,501,669 to Parikh et al. and entitled “Wide Bandgap Transistor Devices With Field Plates”; U.S. Pat. No. 7,126,426 to Mishra et al. and entitled “Cascode Amplifier Structures Including Wide Bandgap Field Effect Transistor With Field Plates”; U.S. Pat. No. 7,550,783 to Wu et al. and entitled “Wide Bandgap HEMTs With Source Connected Field Plates”; U.S. Pat. No. 7,573,078 to Wu et al. and entitled “Wide Bandgap Transistors With Multiple Field Plates”; U.S. Pat. Pub. No. 2005/0253167 to Wu et al. and entitled “Wide Bandgap Field Effect Transistors With Source Connected Field Plates”; U.S. Pat. Pub. No. 2006/0202272 to Wu et al. and entitled “Wide Bandgap Transistors With Gate-Source Field Plates”; U.S. Pat. Pub. No. 2008/0128752 to Wu and entitled “GaN Based HEMTs With Buried Field Plates”; U.S. Pat. Pub. No. 2010/0276698 to Moore et al. and entitled “Gate Electrodes For Millimeter-Wave Operation and Methods of Fabrication; U.S. Pat. Pub. No. 2012/0049973 to Smith, Jr. et al. and entitled “High Power Gallium Nitride Field Effect Transistor Switches”; U.S. Pat. Pub. No. 2012/0194276 to Fisher and entitled “Low Noise Amplifiers Including Group III Nitride Based High Electron Mobility Transistors”; and U.S. Pat. No. 9,847,411 to Sriram et al. entitled “Recessed field plate transistor structures.”

Although embodiments of the inventive concepts have been described in considerable detail with reference to certain configurations thereof, other versions are possible. The three-way Doherty amplifier can also have many different configurations. Accordingly, the spirit and scope of the invention should not be limited to the specific embodiments described above.

What is claimed is:

1. A three-way Doherty amplifier, comprising:
a three-way power splitter configured to receive an input signal and to output a main signal without a phase shift provided at a main splitter output, a first peak signal with a 90° phase shift provided at a first peak signal output, and a second peak signal with a 180° phase shift provided at a second peak signal output;
a main path comprising a main amplifier, a first input network coupled between the main splitter output and the main amplifier, and a main impedance load on the main amplifier configured to impose a main phase offset of 90°;
a first peak path comprising a first peak amplifier, a second input network coupled between the first peak signal output and the first peak amplifier, and a first peak impedance load on the first peak amplifier configured to impose a first peak phase offset of 90°;
a second peak path comprising a second peak amplifier, a third input network coupled between the second peak signal output and the second peak amplifier, and a second peak impedance load on the second peak amplifier; and
a combining node configured to provide an output load impedance to output the main signal during an average power saturation and a combination of the main signal, the first peak signal, and the second peak signal during a peak power saturation;
wherein a first ratio of a gate width of the main amplifier to a first gate width of the first peak amplifier and a second ratio of the gate width of the main amplifier to a second gate width of the second peak amplifier, respectively, are configured to provide a substantially constant load on the main amplifier.

2. The three-way Doherty amplifier of claim 1, wherein, for the main amplifier, a power at the average power is about the same as the power at the peak power.

3. The three-way Doherty amplifier of claim 1, wherein
the main impedance load comprises a main shunt inductor configured to resonate a main drain-source capacitance, Cds, in a frequency band,
the first impedance load comprises a first shunt inductor configured to resonate a first peak Cds in the frequency band, and
the second impedance load comprises a second shunt inductor configured to resonate a second peak Cds in the frequency band.

4. The three-way Doherty amplifier of claim 1, wherein the Doherty combining node comprises a resistive load impedance for 1/(1+P1+P2), where P1 represents a number of pairs of fingers of the first peak amplifier normalized to a number of pairs of fingers of the main amplifier and P2 represents a number of pairs of fingers of the second peak amplifier normalized to the number of pairs of fingers of the main amplifier.

5. The three-way Doherty amplifier of claim 4, wherein the gate width of P1 is greater than the gate width of the pairs of fingers of the main amplifier and the gate width of P2 is greater than the gate width of P1.

6. The three-way Doherty amplifier of claim 1, wherein the first ratio of the gate width of the main amplifier to the first gate width of the first peak amplifier and the second ratio of the gate width of the main amplifier to the second gate width of the second peak amplifier, respectively, are configured to provide a substantially constant load on the main amplifier based on having a same impedance loading on the main amplifier, the first peak amplifier, and the second peak amplifier to cancel load modulation.

7. The three-way Doherty amplifier of claim 1, wherein
the main impedance load comprises a first shunt inductor in series with a first capacitor and a first transmission line or a first lumped equivalent of the first transmission line,
the first peak impedance load comprises a second shunt inductor in series with a second capacitor and a second transmission line or a second lumped equivalent of the second transmission line, and
the second peak impedance load comprises a third shunt inductor in parallel with a third capacitor.

8. The three-way Doherty amplifier of claim 1, wherein the first ratio of the gate width of the main amplifier to the first gate width of the first peak amplifier is 1:1 and the second ratio of the gate width of the main amplifier to the second gate width of the second peak amplifier is 1:2.

9. The three-way Doherty amplifier of claim 8, wherein a ratio of peak power to average power output from the combining node is about −6 dB.

10. The three-way Doherty amplifier of claim 1, wherein the first ratio of the gate width of the main amplifier to the first gate width of the first peak amplifier is 1:2 and the second ratio of the gate width of the main amplifier to the second gate width of the second peak amplifier is 1:6.

11. The three-way Doherty amplifier of claim 10, wherein a ratio of peak power to average power output from the combining node is about −9.5 dB.

12. The three-way Doherty amplifier of claim 1, wherein the first ratio of the gate width of the main amplifier to the first gate width of the first peak amplifier is 1:3 and the second ratio of the gate width of the main amplifier to the second gate width of the second peak amplifier is 1:12.

13. The three-way Doherty amplifier of claim 12, wherein a ratio of peak power to average power output from the combining node is about −12 dB.

14. The three-way Doherty amplifier of claim 1, wherein the first ratio of the gate width of the main amplifier to the first gate width of the first peak amplifier is 1:4 and the second ratio of the gate width of the main amplifier to the second gate width of the second peak amplifier is 1:20.

15. The three-way Doherty amplifier of claim 14, wherein a ratio of peak power to average power output from the combining node is about −14 dB.

16. The three-way Doherty amplifier of claim 1, wherein the main amplifier is a class AB transistor and the first peak amplifier and the second peak amplifier, respectively, are class C transistors.

17. A three-way Doherty amplifier, comprising:
a three-way power splitter configured to receive an input signal and to output a main signal with a 180° phase shift provided at a main splitter output, a first peak signal with a 90° phase shift provided at a first peak signal output, and a second peak signal without a phase shift provided at a second peak signal output;
a main path comprising a main amplifier, a first input network coupled between the main splitter output and the main amplifier, and a main impedance load on the main amplifier configured to impose a main phase offset of 180°;
a first peak path comprising a first peak amplifier, a second input network coupled between the first peak signal output and the first peak amplifier, and a first peak impedance load on the first peak amplifier configured to impose a first peak phase offset of 90°;
a second peak path comprising a second peak amplifier, a third input network coupled between the second peak signal output and the second peak amplifier, and a second peak impedance load on the second peak amplifier to impose a second peak offset of 360°; and
a combining node configured to provide an output load impedance to output the main signal during an average power saturation and a combination of the main signal, the first peak signal, and the second peak signal during a peak power saturation;
wherein a first ratio of a gate width of the main amplifier to a first gate width of the first peak amplifier and a second ratio of the gate width of the main amplifier to a second gate width of the second peak amplifier, respectively, are configured to provide a substantially constant load on the main amplifier.

18. The three-way Doherty amplifier of claim 17, wherein, for the main amplifier, a power at the average power is about the same as the power at the peak power.

19. The three-way Doherty amplifier of claim 17, wherein
the main impedance load comprises a main shunt inductor configured to resonate a main drain-source capacitance, Cds, in a frequency band,
the first impedance load comprises a first shunt inductor configured to resonate a first peak Cds in the frequency band, and
the second impedance load comprises a second shunt inductor configured to resonate a second peak Cds in the frequency band.

20. The three-way Doherty amplifier of claim 17, wherein the Doherty combining node comprises a resistive load impedance for 1/(1+P1+P2), where P1 represents a number of pairs of fingers of the first peak amplifier normalized to a number of pairs of fingers of the main amplifier and P2 represents a number of pairs of fingers of the second peak amplifier normalized to the number of pairs of fingers of the main amplifier.

21. The three-way Doherty amplifier of claim 20, wherein the gate width of P1 is greater than the gate width of the pairs of fingers of the main amplifier and the gate width of P2 is greater than the gate width of P1.

22. The three-way Doherty amplifier of claim 17, wherein the first ratio of the gate width of the main amplifier to the first gate width of the first peak amplifier and the second ratio of the gate width of the main amplifier to the second gate width of the second peak amplifier, respectively, are configured to provide a substantially constant load on the main amplifier based on having a same impedance loading on the main amplifier, the first peak amplifier, and the second peak amplifier to cancel load modulation.

23. The three-way Doherty amplifier of claim 17, wherein
the main impedance load comprises a first shunt inductor in series with a first capacitor and a first and second transmission line or a first lumped equivalent of the first and/or second transmission line,
the first peak impedance load comprises a second shunt inductor in series with a second capacitor and a third transmission line or a third lumped equivalent of the third transmission line, and
the second peak impedance load comprises a fourth shunt inductor in series with a fourth capacitor and a fourth transmission line or a lumped equivalent of the fourth transmission line.

24. The three-way Doherty amplifier of claim 17, wherein the first ratio of the gate width of the main amplifier to the first gate width of the first peak amplifier is 1:1 and the second ratio of the gate width of the main amplifier to the second gate width of the second peak amplifier is 1:2.

25. The three-way Doherty amplifier of claim 24, wherein a ratio of peak power to average power output from the combining node is about −6 dB.

26. The three-way Doherty amplifier of claim 17, wherein the first ratio of the gate width of the main amplifier to the first gate width of the first peak amplifier is 1:2 and the second ratio of the gate width of the main amplifier to the second gate width of the second peak amplifier is 1:6.

27. The three-way Doherty amplifier of claim 26, wherein a ratio of peak power to average power output from the combining node is about −9.5 dB.

28. The three-way Doherty amplifier of claim 17, wherein the first ratio of the gate width of the main amplifier to the first gate width of the first peak amplifier is 1:3 and the second ratio of the gate width of the main amplifier to the second gate width of the second peak amplifier is 1:12.

29. The three-way Doherty amplifier of claim 28, wherein a ratio of peak power to average power output from the combining node is about −12 dB.

30. The three-way Doherty amplifier of claim 17, wherein the first ratio of the gate width of the main amplifier to the first gate width of the first peak amplifier is 1:4 and the second ratio of the gate width of the main amplifier to the second gate width of the second peak amplifier is 1:20.

31. The three-way Doherty amplifier of claim 30, wherein a ratio of peak power to average power output from the combining node is about −14 dB.

32. The three-way Doherty amplifier of claim 1, wherein the main amplifier is a class AB transistor and the first peak amplifier and the second peak amplifier, respectively, are class C transistors.

33. A three-way Doherty amplifier, comprising:
a two-way power splitter configured to receive an input signal and to output a first signal with a 90° phase shift provided at a first splitter output, and a second signal without a phase shift provided at a second splitter output;
a first path comprising a main device comprising a first amplifier and a second amplifier, a first input network coupled between the first splitter signal output and the main device, and a first impedance load on the main device configured to impose a phase offset of 90°;
a second path comprising a third amplifier, a second input network coupled between the second splitter signal output and the third amplifier, and a second peak impedance load on the third amplifier configured to impose a second peak phase offset of 180°; and
a combining node configured to provide an output load impedance to output a main signal during an average power saturation and a combination of the main signal, and the second signal during a peak power saturation;
wherein a first ratio of a gate width of the first amplifier to a first gate width of the second amplifier and a second ratio of the gate width of the first amplifier to a second gate width of the third amplifier, respectively, are configured to provide a substantially constant load on the main device.

34. The three-way Doherty amplifier of claim 33, wherein, for the main device, a power at the average power is about the same as the power at the peak power.

35. The three-way Doherty amplifier of claim 33, wherein
the first impedance load comprises a first shunt inductor configured to resonate a first drain-source capacitance, Cds, and a second Cds in a frequency band, and
the second impedance load comprises a second shunt inductor configured to resonate a third Cds in the frequency band.

36. The three-way Doherty amplifier of claim 33, wherein the Doherty combining node comprises a resistive load impedance for 1/(1+P1+P2), where P1 represents a number of pairs of fingers of the second amplifier normalized to a number of pairs of fingers of the first amplifier and P2 represents a number of pairs of fingers of the third amplifier normalized to the number of pairs of fingers of the first amplifier.

37. The three-way Doherty amplifier of claim 36, wherein the gate width of P1 is greater than the gate width of the pairs of fingers of the main amplifier and the gate width of P2 is greater than the gate width of P1.

38. The three-way Doherty amplifier of claim 33, wherein the first ratio of the gate width of the first amplifier to the first gate width of the second amplifier and the second ratio of the gate width of the first amplifier to the second gate width of the third amplifier, respectively, are configured to provide a substantially constant load on the main device based on having a same impedance loading on the first amplifier, the second amplifier, and the third amplifier to cancel load modulation.

39. The three-way Doherty amplifier of claim 33, wherein
the first impedance load comprises a first shunt inductor in series with a first capacitor and a first transmission line or a first lumped equivalent of the first transmission line, and
the second impedance load comprises a second shunt inductor in series with a second capacitor and a second transmission line or a second lumped equivalent of the second transmission line.

40. The three-way Doherty amplifier of claim 33, wherein the first ratio of the gate width of the first amplifier to the first gate width of the second amplifier is 1:1 and the second ratio of the gate width of the first amplifier to the second gate width of the third amplifier is 1:2.

41. The three-way Doherty amplifier of claim 40, wherein a ratio of peak power to average power output from the combining node is about −6 dB.

42. The three-way Doherty amplifier of claim 33, wherein the first ratio of the gate width of the first amplifier to the first gate width of the second amplifier is 1:2 and the second ratio of the gate width of the first amplifier to the second gate width of the third amplifier is 1:6.

43. The three-way Doherty amplifier of claim 42, wherein a ratio of peak power to average power output from the combining node is about −9.5 dB.

44. The three-way Doherty amplifier of claim 33, wherein the first ratio of the gate width of the first amplifier to the first gate width of the second amplifier is 1:3 and the second ratio of the gate width of the first amplifier to the second gate width of the third amplifier is 1:12.

45. The three-way Doherty amplifier of claim 44, wherein a ratio of peak power to average power output from the combining node is about −12 dB.

46. The three-way Doherty amplifier of claim 33, wherein the first ratio of the gate width of the first amplifier to the first gate width of the second amplifier is 1:4 and the second ratio of the gate width of the first amplifier to the second gate width of the third amplifier is 1:20.

47. The three-way Doherty amplifier of claim 46, wherein a ratio of peak power to average power output from the combining node is about −14 dB.

48. The three-way Doherty amplifier of claim 33, wherein the first amplifier is a class AB transistor and the second amplifier and the third amplifier, respectively, are class C transistors.

49. A three-way Doherty amplifier, comprising:
a main path comprising a main amplifier, a main input network coupled between a main splitter output and the main amplifier, and a main output network coupled between the main amplifier and a combining node;
a first peak path comprising a first peak amplifier, a second input network coupled between a first peak signal output and the first peak amplifier, and a first peak output network coupled between the first peak amplifier and the combining node; and
a second peak path comprising a second peak amplifier, a third input network coupled between a second peak signal output and the second peak amplifier, and a second peak output network coupled between the second peak amplifier and the combining node,
wherein a first ratio of a gate width of the main amplifier to a first gate width of the first peak amplifier and a second ratio of the gate width of the main amplifier to a second gate width of the second peak amplifier, respectively, are configured to provide a substantially constant load on the main amplifier.

50. A three-way Doherty amplifier, comprising:
a first path comprising a main device comprising a first amplifier and a second amplifier, a first input network coupled between a first splitter signal output and the main device, and a first output network coupled between the main device and a combining node; and
a second path comprising a third amplifier, a second input network coupled between a second splitter signal output and the third amplifier, and a second output network coupled between the third amplifier and the combining node,
wherein a first ratio of a gate width of the first amplifier to a first gate width of the second amplifier and a second ratio of the gate width of the first amplifier to a second gate width of the third amplifier, respectively, are configured to provide a substantially constant load on the main device.
